(19) United States
(12) Patent Application Publication
(10) Pub. No.: US 2021/0229222 A1
(43) Pub. Date: Jul. 29, 2021

(54) SOLDER PARTICLES AND METHOD FOR PRODUCING SOLDER PARTICLES

(71) Applicant: Showa Denko Materials Co., Ltd., Tokyo (JP)

(72) Inventors: Kunihiko AKAI, Chiyoda-ku, Tokyo (JP); Yoshinori EJIRI, Chiyoda-ku, Tokyo (JP); Yuuhei OKADA, Chiyoda-ku, Tokyo (JP); Toshimitsu MORIYA, Chiyoda-ku, Tokyo (JP); Shinichirou SUKATA, Chiyoda-ku, Tokyo (JP); Masayuki MIYAJI, Chiyoda-ku, Tokyo (JP)

(73) Assignee: Showa Denko Materials Co., Ltd., Tokyo (JP)

(21) Appl. No.: 17/255,988

(22) PCT Filed: Jun. 26, 2019
(86) PCT No.: PCT/JP2019/025497

§ 371 Date: Dec. 23, 2020

(30) Foreign Application Priority Data
Jun. 26, 2018 (JP) 2018-121088
Jan. 30, 2019 (JP) 2019-014852

(51) Int. Cl. B23K 35/02; C22C 13/00; C22C 12/00; B23K 35/26; B22F 9/04; B22F 1/00

(52) U.S. Cl. CPC B23K 35/0244; C22C 13/00; C22C 12/00; B23K 35/262; B22F 2301/30; B22F 9/04; B22F 1/0011; B22F 2304/10; B23K 35/264

(57) ABSTRACT

A method for producing solder particles, which includes: a preparation step wherein a base material that has a plurality of recesses and solder fine particles are prepared; an accommodation step wherein at least some of the solder fine particles are accommodated in the recesses; and a fusing step wherein the solder fine particles accommodated in the recesses are fused, thereby forming solder particles within the recesses. With respect to this method for producing solder particles, the average particle diameter of the solder particles is from 1 μm to 30 μm; and the C.V. value of the solder particles is 20% or less.

### TECHNICAL FIELD

The present invention relates to solder particles and a method for producing solder particles.

### BACKGROUND ART

In the related art, use of solder particles as conductive particles mixed into anisotropic conductive materials such as anisotropic conductive films and anisotropic conductive pastes has been studied. For example, in Patent Literature 1, a conductive paste containing a thermosetting component and a plurality of solder particles subjected to a specific surface treatment is described.

### REFERENCE LIST

### Patent Literature

Patent Literature 1: Japanese Patent Laid-Open No. 2016-76494

### SUMMARY OF INVENTION

### Technical Problem

In recent years, connecting parts have been miniaturized further, and as the definition of circuit members has been higher, the conduction reliability and the insulation reliability required for anisotropic conductive materials have increased. In order to secure conduction reliability and insulation reliability, it is necessary to further miniaturize and homogenize conductive particles mixed into anisotropic conductive materials. However, in the method for producing solder particles in the related art, it has been difficult to produce solder particles having both a small average particle diameter and a narrow particle size distribution.

The present invention has been made in view of the above circumstances, and an objective of the present invention is to provide a method for producing solder particles, which allows solder particles having both a small average particle diameter and a narrow particle size distribution to be easily produced. In addition, an objective of the present invention is to provide solder particles having both a small average particle diameter and a narrow particle size distribution according to the production method.

### Solution to Problem

One aspect of the present invention relates to a method for producing solder particles including a preparation step in which a base material having a plurality of recesses and solder fine particles are prepared; an insertion step in which at least some of the solder fine particles are accommodated in the recesses; and a fusing step in which the solder fine particles accommodated in the recesses are fused and the solder particles are thus formed inside the recesses. The solder particles produced by the production method have an average particle diameter of 1 μm to 30 μm and the solder particles have a C.V. value of 20% or less.

In one aspect, the C.V. value of the solder fine particles prepared in the preparation step may be more than 20%. When such solder fine particles are used, a rate of filling the solder fine particles into the recesses increases, and more uniform solder particles can be easily obtained.

In one aspect, before the fusing step, the solder fine particles accommodated in the recesses may be exposed to a reducing atmosphere.

In one aspect, the fusing step may be a step in which the solder fine particles accommodated in the recesses are fused under a reducing atmosphere.

In one aspect, the fusing step may be a step in which the solder fine particles accommodated in the recesses are fused under an atmosphere with a temperature equal to or higher than a melting point of the solder fine particles.

In one aspect, the solder fine particles prepared in the preparation step may include at least one selected from the group consisting of tin, tin alloys, indium and indium alloys.

In one aspect, the solder fine particles prepared in the preparation step may include at least one selected from the group consisting of In—Bi alloys, In—Sn alloys, In—Sn—Ag alloys, Sn—Au alloys, Sn—Bi alloys, Sn—Bi—Ag alloys, Sn—Ag—Cu alloys and Sn—Cu alloys.

Another aspect of the present invention relates to solder particles having an average particle diameter of 1 μm to 30 μm and a C.V. value of 20% or less.

In solder particles according to one aspect, a quadrangle circumscribing a projected image of a solder particle is created by two pairs of parallel lines, and distances between opposite sides are set as X and Y (where Y<X), X and Y may satisfy the following formula:

0.8<Y/X<1.0.

Solder particles according to one aspect may include at least one selected from the group consisting of tin, tin alloys, indium and indium alloys.

Solder particles according to one aspect may include at least one selected from the group consisting of In—Bi alloys, In—Sn alloys, In—Sn—Ag alloys, Sn—Au alloys, Sn—Bi alloys, Sn—Bi—Ag alloys, Sn—Ag—Cu alloys and Sn—Cu alloys.

### Advantageous Effects of Invention

According to the present invention, there is provided a method for producing solder particles, which allows solder particles having both a small average particle diameter and a narrow particle size distribution to be easily produced. In addition, according to the present invention, there are provided solder particles having both a small average particle diameter and a narrow particle size distribution.

### BRIEF DESCRIPTION OF DRAWINGS

(a) of FIG. 1 is a plan view schematically showing an example of a base material, and (b) of FIG. 1 is a cross-sectional view taken along the line Ib-Ib shown in (a) of FIG. 1.

(a) of FIG. 2 to (h) of FIG. 2 are cross-sectional views schematically showing an example of a cross-sectional shape of recesses of the base material.

FIG. 3 is a cross-sectional view schematically showing a state in which solder fine particles are accommodated in recesses of the base material.

FIG. 4 is a cross-sectional view schematically showing a state in which solder particles are formed in recesses of the base material.

FIG. 5 is a diagram of solder particles when viewed from the side opposite to an opening part of the recess in FIG. 4.

FIG. 6 is a diagram showing distances X and Y (where YX) between opposite sides when a quadrangle circumscribing a projected image of a solder particle is created by two pairs of parallel lines.

(a) of FIG. 7 and (b) of FIG. 7 are diagrams showing an SEM image of solder particles formed in Example 17.

(a) of FIG. 8 and (b) of FIG. 8 are diagrams showing an SEM image of solder particles used in Comparative Production Example 1.

FIG. 9 is a cross-sectional view schematically showing another example of a cross-sectional shape of the recess of the base material.

### DESCRIPTION OF EMBODIMENTS

Hereinafter, embodiments of the present invention will be described. The present invention is not limited to the following embodiments. Here, unless otherwise specified, materials exemplified below may be used alone or two or more thereof may be used in combination. When there are a plurality of substances corresponding to components in a composition, the content of the components in the composition means a total amount of the plurality of substances present in the composition unless otherwise specified. A numerical range indicated using “to” means a range including numerical values stated before and after “to” as a minimum value and a maximum value. In the numerical ranges described stepwise in this specification, an upper limit value or a lower limit value of a certain stepwise numerical range may be replaced with an upper limit value or a lower limit value of other stepwise numerical ranges. In the numerical ranges described in this specification, the upper limit value or the lower limit value of the numerical range may be replaced with values shown in examples.

### <Method for Producing Solder Particles>

A method for producing solder particles according to the present embodiment is a method for producing solder particles having an average particle diameter of 1 μm to 30 μm, and includes a preparation step in which a base material having a plurality of recesses and solder fine particles are prepared, an accommodation step in which at least some of the solder fine particles are accommodated in the recesses of the base material, and a fusing step in which the solder fine particles accommodated in the recesses are fused and the solder particles are formed inside the recesses. According to this production method, solder particles having an average particle diameter of 1 μm to 30 μm and a C.V. value of 20% or less are produced.

A method for producing solder particles will be described below with reference to FIGS. 1 to 5.

First, solder fine particles and a base material 60 in which solder fine particles are contained are prepared. (a) of FIG. 1 is a plan view schematically showing an example of the base material 60, and (b) of FIG. 1 is a cross-sectional view taken along the line Ib-Ib shown in (a) of FIG. 1. The base material 60 shown in (a) of FIG. 1 has a plurality of recesses 62. The plurality of recesses 62 may be regularly arranged in a predetermined pattern. In this case, after solder particles are formed in the recesses 62, the solder particles in the recesses 62 are transferred to a resin material or the like, and thus the solder particles can be regularly arranged.

The recesses 62 of the base material 60 are preferably formed in a tapered shape in which an opening area enlarges from the side of a bottom 62a of the recesses 62 toward the side of a surface 60a of the base material 60. That is, as shown in FIG. 1, the width (a width a in FIG. 1) of the bottom 62a of the recesses 62 is preferably narrower than the width (a width b in FIG. 1) of an opening on the surface 60a of the recesses 62. In addition, the size (a width a, a width b, a volume, a taper angle, a depth, etc.) of the recesses 62 may be set according to the size of desired solder particles.

Here, the shape of the recesses 62 may be a shape other than the shape shown in FIG. 1. For example, the shape of the opening on the surface 60a of the recesses 62 may be an ellipse, a triangle, a quadrangle, a polygon or the like, in addition to a circle as shown in FIG. 1.

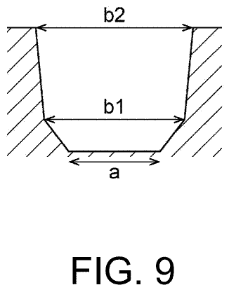

In addition, the shape of the recesses 62 in the cross section perpendicular to the surface 60a may be, for example, a shape shown in FIG. 2. (a) of FIG. 2 to (h) of FIG. 2 are cross-sectional views schematically showing an example of a cross-sectional shape of the recess of the base material. In each of the cross-sectional shapes shown in (a) of FIG. 2 to (h) of FIG. 2, the width (the width b) of the opening on the surface 60a of the recesses 62 is the maximum width in the cross-sectional shape. Thereby, it is easy to contain solder fine particles in the recesses 62 and it is easy to remove the solder particles formed in the recesses 62, and thus the workability is improved. In addition, the shape of the recesses 62 in the cross section perpendicular to the surface 60a may be, for example, as shown in FIG. 9, a shape in which the wall surface in the cross-sectional shape shown in (a) of FIG. 2 to (h) of FIG. 2 is inclined. It can be said that FIG. 9 shows a shape in which the wall surface of the cross-sectional shape shown in (b) of FIG. 2 is inclined.

Regarding the material constituting the base material 60, for example, an inorganic material such as silicon, various ceramics, glass, and a metal such as stainless steel, and an organic material such as various resins can be used. Among these, the base material 60 is preferably formed of a heat-resistant material that does not deteriorate at a melting temperature of the solder fine particles. In addition, the recesses 62 of the base material 60 can be formed by a known method such as a photolithography method.

The solder fine particles prepared in the preparation step may include fine particles having a particle diameter smaller than the width (the width b) of the opening on the surface 60a of the recesses 62, and preferably include more fine particles having a particle diameter smaller than the width b. For example, in the solder fine particles, the D10 particle diameter of the particle size distribution is preferably smaller than the width b, the D30 particle diameter of the particle size distribution is more preferably smaller than the width b, and the D50 particle diameter of the particle size distribution is still more preferably smaller than the width b.

The particle size distribution of the solder fine particles can be measured using various methods according to the size. Methods, for example, a dynamic light scattering method, a laser diffraction method, a centrifugal sedimentation method, an electrical detection band method, and a resonance type mass measurement method, can be used. In addition, a method of measuring a particle size from an image obtained by an optical microscope, an electron microscope or the like can be used. Examples of specific devices include a flow type particle image analyzing device, a Microtrac, and a Coulter counter.

The C.V. value of the solder fine particles prepared in the preparation step is not particularly limited, and in order to improve filling into the recesses 62 according to a combination of large and small fine particles, a high C.V. value is preferable. For example, the C.V. value of the solder fine particles may be more than 20%, and is preferably 25% or more and more preferably 30% or more.

The C.V. value of the solder fine particles is calculated by multiplying a value obtained by dividing the standard deviation of particle diameters measured by the above method by the average particle diameter (D50 particle diameter) by 100.

The solder fine particles may contain tin or a tin alloy. Regarding the tin alloy, for example, In—Sn alloys, In—Sn—Ag alloys, Sn—Au alloys, Sn—Bi alloys, Sn—Bi—Ag alloys, Sn—Ag—Cu alloys, and Sn—Cu alloys can be used. Specific examples of these tin alloys include the following examples.
In—Sn (In 52 mass %, Bi 48 mass %, melting point of 118° C.)
In—Sn—Ag (In 20 mass %, Sn 77.2 mass %, Ag 2.8 mass %, melting point of 175° C.)
Sn—Bi (Sn 43 mass %, Bi 57 mass %, melting point of 138° C.)
Sn—Bi—Ag (Sn 42 mass %, Bi 57 mass %, Ag 1 mass %, melting point of 139° C.)
Sn—Ag—Cu (Sn 96.5 mass %, Ag 3 mass %, Cu 0.5 mass %, melting point of 217° C.)
Sn—Cu (Sn 99.3 mass %, Cu 0.7 mass %, melting point of 227° C.)
Sn—Au (Sn 21.0 mass %, Au 79.0 mass %, melting point of 278° C.)

The solder particles may contain indium or an indium alloy. Regarding the indium alloy, for example, In—Bi alloys and In—Ag alloys can be used. Specific examples of these indium alloys include the following examples.
In—Bi (In 66.3 mass %, Bi 33.7 mass %, melting point of 72° C.)
In—Bi (In 33.0 mass %, Bi 67.0 mass %, melting point of 109° C.)
In—Ag (In 97.0 mass %, Ag 3.0 mass %, melting point of 145° C.)

The tin alloy or indium alloy can be selected according to applications of the solder particles (temperature during use). For example, when it is desired to obtain solder particles used for fusion at a low temperature, In—Sn alloys and Sn—Bi alloys may be used, and in this case, solder particles that can be fused at 150° C. or lower are obtained. When a material having a high melting point such as Sn—Ag—Cu alloys and Sn—Cu alloys is used, solder particles that can maintain high reliability even after being left at a high temperature can be obtained.

The solder fine particles may contain at least one selected from among Ag, Cu, Ni, Bi, Zn, Pd, Pb, Au, P and B. Among these elements, Ag or Cu may be contained in consideration of the following aspect. That is, when the solder fine particles contain Ag or Cu, effects in which the melting point of the obtained solder particles can be lowered to about 220° C. and the solder particles having an excellent bond strength with respect to an electrode are obtained, and thus more favorable conduction reliability is obtained are obtained.

The Cu content of the solder fine particles is, for example, 0.05 to 10 mass %, and may be 0.1 to 5 mass % or 0.2 to 3 mass %. When the Cu content is 0.05 mass % or more, it is easy to obtain solder particles that allow favorable solder connection reliability to be achieved. In addition, when the Cu content is 10 mass % or less, solder particles having a low melting point and excellent wettability are easily obtained, and as a result, the reliability of connection of the bonding part to the solder particles tends to be better.

The Ag content of the solder fine particles is, for example, 0.05 to 10 mass %, and may be 0.1 to 5 mass % or 0.2 to 3 mass %. When the Ag content is 0.05 mass % or more, it is easy to obtain solder particles that allow favorable solder connection reliability to be achieved. In addition, when the Ag content is 10 mass % or less, solder particles having a low melting point and excellent wettability are easily obtained, and as a result, the reliability of connection of the bonding part to the solder particles tends to be better.

In the accommodation step, the solder fine particles prepared in the preparation step are accommodated in each of the recesses 62 of the base material 60. The accommodation step may be a step in which all of the solder fine particles prepared in the preparation step are accommodated in the recesses 62 or a step in which some of the solder fine particles prepared in the preparation step (for example, those having a diameter smaller than the width b of the opening of the recesses 62 among the solder fine particles) are accommodated in the recesses 62.

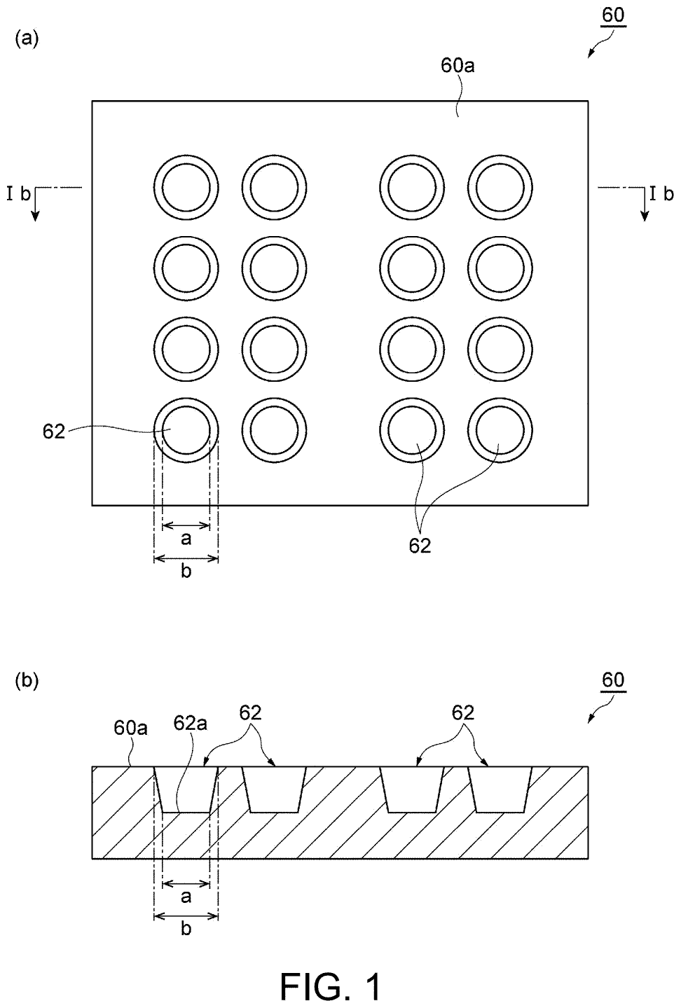

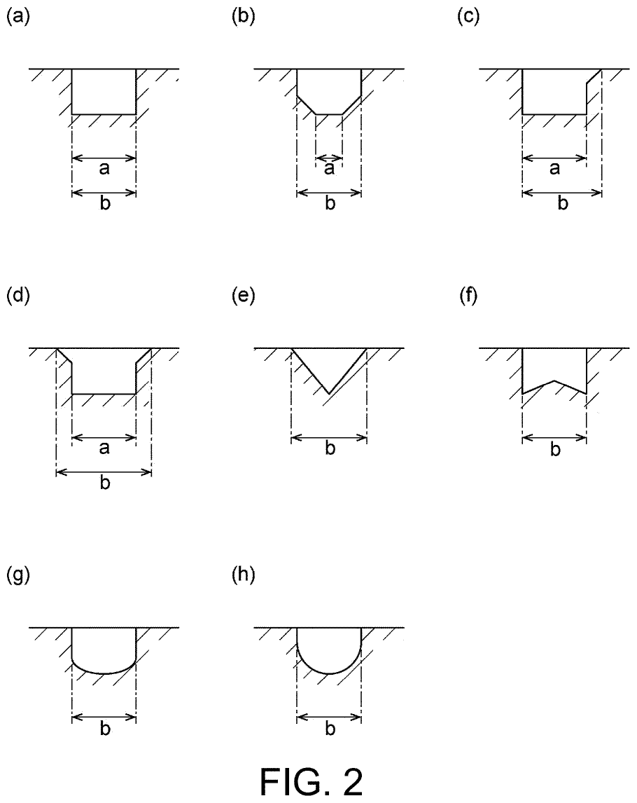

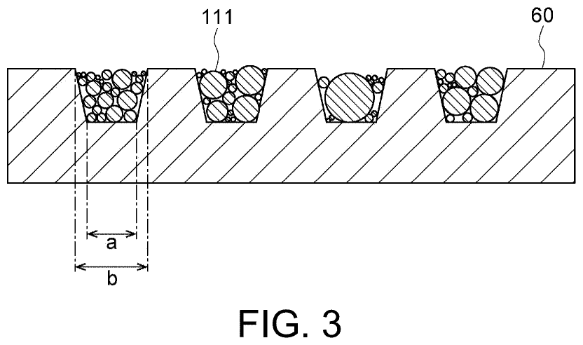

FIG. 3 is a cross-sectional view schematically showing a state in which solder fine particles 111 are accommodated in the recesses 62 of the base material 60. As shown in FIG. 3, the plurality of solder fine particles 111 are accommodated in each of the plurality of recesses 62.

For example, the amount of the solder fine particles 111 accommodated in the recesses 62 is preferably 20% or more, more preferably 30% or more, still more preferably 50% or more, and most preferably 60% or more with respect to the volume of the recesses 62. Thereby, the variation in the accommodation amount is minimized and solder particles having a smaller particle size distribution are easily obtained.

A method of accommodating solder fine particles in the recesses 62 is not particularly limited. The accommodation method may be any of a dry type and a wet type. For example, when the solder fine particles prepared in the preparation step are placed on the base material 60 and the surface 60a of the base material 60 is rubbed with a squeegee, excess solder fine particles can be removed and sufficient solder fine particles can be accommodated in the recesses 62. When the width b of the opening of the recesses 62 is larger than the depth of the recesses 62, the solder fine particles protrude from the opening of the recesses 62. When the squeegee is used, the solder fine particles protruding from the opening of the recesses 62 are removed. Examples of a method of removing excess solder fine particles include a method of spraying compressed air and a method of rubbing the surface 60a of the base material 60 with a non-woven fabric or fiber bundle. These methods are preferable for handling easily deformable solder fine particles because a physical power is weaker than that of the squeegee. In addition, in these methods, solder fine particles protruding from the opening of the recesses 62 can remain in the recess.

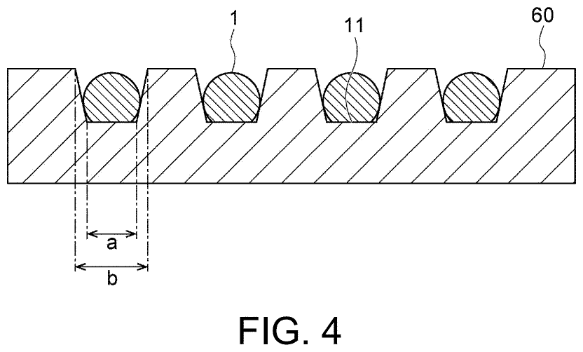

The fusing step is a step in which the solder fine particles 111 accommodated in the recesses 62 are fused, and solder particles 1 are formed inside the recesses 62. FIG. 4 is a cross-sectional view schematically showing a state in which the solder particles 1 are formed in the recesses 62 of the base material 60. The solder fine particles 111 accommodated in the recesses 62 are melted and coalesced, and spheroidized due to surface tension. In this case, at a part in contact with the bottom 62a of the recesses 62, the molten solder forms a flat portion 11 conforming to the bottom 62a. Thereby, the formed solder particles 1 have a shape having a flat portion 11 on a part of the surface.

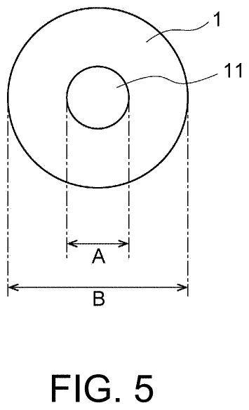

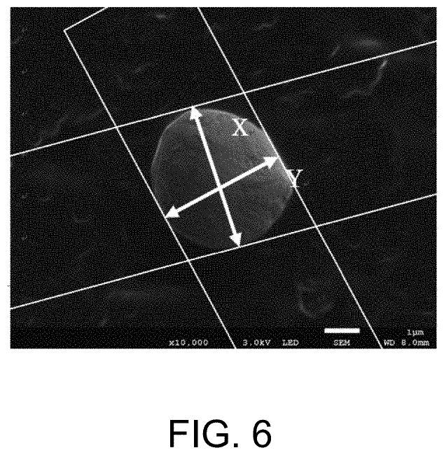

FIG. 5 is a diagram of the solder particles 1 when viewed from the side opposite to the opening part of the recesses 62 in FIG. 4. The solder particles 1 have a shape in which a flat portion 11 having a diameter A is formed on a part of the surface of a sphere having a diameter B. Here, the solder particles 1 shown in FIG. 4 and FIG. 5 have the flat portion 11 because the bottom 62a of the recesses 62 is flat, but when the bottom 62a of the recesses 62 has a shape other than a flat surface, the solder particles 1 have a surface having a different shape corresponding to the shape of the bottom 62a.

Examples of a method of melting the solder fine particles 111 accommodated in the recesses 62 include a method of heating the solder fine particles 111 to a melting point of the solder or higher. Due to the influence of an oxide film, even if heated to a temperature equal to or higher than the melting point, the solder fine particles 111 may not melt, may not wet and spread, or may not coalesce. Therefore, when the solder fine particles 111 are exposed to a reducing atmosphere, the oxide film on the surface the solder fine particles 111 is removed and heating is then performed at a temperature equal to or higher than the melting point of the solder fine particles 111, the solder fine particles 111 can be melted, wet and spread, and coalesced. In addition, the solder fine particles 111 are preferably melted under a reducing atmosphere. When the solder fine particles 111 are heated to a temperature equal to or higher than the melting point of the solder fine particles 111 and a reducing atmosphere is created, the oxide film on the surface of the solder fine particles 111 is reduced, the solder fine particles 111 are efficiently and easily melted, wet and spread, and coalesced.

The method of creating a reducing atmosphere is not particularly limited as long as the above effects are obtained, and for example, a method using hydrogen gas, hydrogen radicals, formic acid gas, or the like may be used. For example, the solder fine particles 111 can be melted under a reducing atmosphere using a hydrogen reduction furnace, a hydrogen radical reduction furnace, a formic acid reduction furnace, or a conveyor furnace or a consecutive series of such furnaces. In these devices, the furnace may include a heating device, a chamber filled with an inert gas (nitrogen, argon, etc.), a mechanism for evacuating the inside of the chamber and the like, and thereby a reducing gas is more easily controlled. In addition, when the inside of the chamber can be evacuated, after the solder fine particles 111 are melted and coalesced, voids can be removed due to a reduced pressure, and the solder particles 1 having superior connection stability can be obtained.

Profiles such as reducing and dissolving conditions for the solder fine particles 111, the temperature, and adjustment of the atmosphere in the furnace may be appropriately set in consideration of the melting point of the solder fine particles 111, the particle size, the size of the recess, and the material of the base material 60. For example, the base material 60 in which the solder fine particles 111 are filled into recesses is inserted into a furnace, the furnace is evacuated, a reducing gas is then introduced, the inside of the furnace is filled with a reducing gas, the oxide film on the surface of the solder fine particles 111 is removed, the reducing gas is then removed by evacuation, heating is then performed to a temperature equal to or higher than the melting point of the solder fine particles 111, the solder fine particles are dissolved and coalesced, the solder particles are formed in the recesses 62, the temperature in the furnace is then returned to room temperature after filling with nitrogen gas, and thus the solder particles 1 can be obtained. In addition, for example, the base material 60 in which the solder fine particles 111 are filled into recesses is inserted into a furnace, the furnace is evacuated, a reducing gas is then introduced, the inside of the furnace is filled with a reducing gas, the solder fine particles 111 are heated by a heating heater in the furnace, the oxide film on the surface of the solder fine particles 111 is removed, the reducing gas is then removed by evacuation, heating is then performed to a temperature equal to or higher than the melting point of the solder fine particles 111, the solder fine particles are dissolved and coalesced, the solder particles are formed in the recesses 62, the temperature in the furnace is then returned to room temperature after filling with nitrogen gas, and thus the solder particles 1 can be obtained. When the solder fine particles are heated under a reducing atmosphere, there are advantages that the reducing power increases and the oxide film on the surface of the solder fine particles is easily removed.

In addition, for example, the base material 60 in which the solder fine particles 111 are filled into recesses is inserted into a furnace, the furnace is evacuated, a reducing gas is then introduced, the inside of the furnace is filled with a reducing gas, the base material 60 are heated to a temperature equal to or higher than the melting point of the solder fine particles 111 by a heating heater in the furnace, the oxide film on the surface of the solder fine particles 111 is removed by reduction, and at the same time, the solder fine particles are dissolved and coalesced, the solder particles are formed in the recesses 62, the reducing gas is removed by evacuation, and additionally, the number of voids in the solder particles is reduced, the temperature in the furnace is then returned to room temperature after filling with nitrogen gas, and thus the solder particles 1 can be obtained. In this case, since it is easy to adjust the increase and decrease of the temperature in the furnace once, there is an advantage that processing can be performed in a short time.

A step in which the inside of the furnace is made into a reducing atmosphere again and the oxide film on the surface that has not been completely removed is removed after the solder particles are formed in the recesses 62 may be additionally performed. Thereby, it is thus possible to reduce the amount of residue such as remaining unfused solder fine particles and a part of the unfused remaining oxide film.

When an atmospheric pressure conveyor furnace is used, the base material 60 in which the solder fine particles 111 are filled into recesses is placed on a transport conveyor and is caused to pass through a plurality of zones consecutively, and thus the solder particles 1 can be obtained. For example, the base material 60 in which the solder fine particles 111 are filled into recesses is placed on a conveyor set at a certain speed and caused to pass through a zone filled with an inert gas such as nitrogen or argon with a temperature lower than the melting point of the solder fine particles 111 and subsequently pass through a zone in which a reducing gas such as formic acid gas with a temperature lower than the melting point of the solder fine particles 111 is provided, the oxide film on the surface of the solder fine particles 111 is removed, and subsequently the material is caused to pass through a zone filled with an inert gas such as nitrogen and argon with a temperature equal to or higher than the melting point of the solder fine particles 111, the solder fine particles 111 are melted and coalesced, and subsequently the material is caused to pass through a cooling zone filled with an inert gas such as nitrogen and argon, and thus the solder particles 1 can be obtained. For example, the base material 60 in which the solder fine particles 111 are filled into recesses is placed on a conveyor set at a certain speed and caused to pass through a zone filled with an inert gas such as nitrogen and argon with a temperature equal to or higher than the melting point of the solder fine particles 111, subsequently pass through a zone in which a reducing gas such as formic acid gas with a temperature equal to or higher than the melting point of the solder fine particles 111 is provided, the oxide film on the surface of the solder fine particles 111 is removed, and melting and coalescing are performed, subsequently the material is caused to pass through a cooling zone filled with an inert gas such as nitrogen and argon, and thus the solder particles 1 can be obtained. Since the above conveyor furnace can perform processing at atmospheric pressure, it is possible to continuously process a film-like material in a roll to roll method. For example, a continuous roll product of the base material 60 in which the solder fine particles 111 are filled into recesses is produced, a roller unwinding machine is installed on the inlet side of the conveyor furnace, a roller winding machine is installed on the exit side of the conveyor furnace, the base material 60 is transported at a certain speed and caused to pass through zones in the conveyor furnace, and thus the solder fine particles 111 filled into the recesses can be fused.

The formed solder particles 1 that are accommodated in the recesses 62 of the base material 60 may be transported or stored, and the formed solder particles 1 may be removed from the recesses 62 and collected. In addition, a resin material is disposed on the surface 60a of the base material 60, and the solder particles 1 in the recesses 62 may be transferred to the resin material. In this case, when the recesses 62 are regularly arranged, the solder particles 1 can be regularly arranged on the resin material.

According to the production method of the present embodiment, it is possible to form solder particles having a uniform size regardless of the material and shape of the solder fine particles. For example, indium-based solder can be precipitated by plating, but is unlikely to be precipitated in the form of particles and is hard to handle because it is soft. However, in the production method of the present embodiment, it is possible to easily produce indium-based solder particles having a uniform particle diameter using indium-based solder fine particles as a raw material. In addition, since the formed solder particles 1 that are accommodated in the recesses 62 of the base material 60 can be handled, the solder particles can be transported and stored without being deformed. In addition, since the formed solder particles 1 are simply accommodated in the recesses 62 of the base material 60, they can be easily removed, and the solder particles can be collected and subjected to a surface treatment and the like without being deformed.

In addition, the solder fine particles 111 may have a large variation in the particle size distribution or may have a distorted shape but can be used as a raw material in the production method of the present embodiment as long as they can be accommodated in the recesses 62.

In addition, in the production method of the present embodiment, in the base material 60, the shape of the recesses 62 can be freely designed according to a photolithography method, an imprint method, a machining method, an electron beam processing method, a radiation processing method, or the like. Since the size of the solder particles 1 depends on the amount of the solder fine particles 111 accommodated in the recesses 62, in the production method of the present embodiment, the size of the solder particles 1 can be freely designed according to designing of the recesses 62.

### (Solder Particles)

The solder particles according to the present embodiment have an average particle diameter of 1 μm to 30 μm and a C.V. value of 20% or less. Such solder particles have both a small average particle diameter and a narrow particle size distribution, and can be suitably used as conductive particles applied to an anisotropic conductive material having high conduction reliability and insulation reliability. The solder particles according to the present embodiment are produced by the above production method.

The average particle diameter of the solder particles is not particularly limited as long as it is within the above range, and is preferably 30 μm or less, more preferably 25 μm or less, and still more preferably 20 μm or less. In addition, the average particle diameter of the solder particles is preferably 1 μm or more, more preferably 2 μm or more, and still more preferably 4 μm or more.

The average particle diameter of the solder particles can be measured using various methods according to the size. For example, a dynamic light scattering method, a laser diffraction method, a centrifugal sedimentation method, an electrical detection band method, and a resonance type mass measurement method, can be used. In addition, a method of measuring a particle size from an image obtained by an optical microscope, an electron microscope or the like can be used. Examples of specific devices include a flow type particle image analyzing device, a Microtrac, and a Coulter counter.

In order to realize better conduction reliability and insulation reliability, the C.V. value of the solder particles is preferably 20% or less, more preferably 10% or less, still more preferably 7% or less, and particularly preferably 5% or less. In addition, the lower limit of the C.V. value of the solder particles is not particularly limited. For example, the C.V. value of the solder particles may be 1% or more or 2% or more.

The C.V. value of the solder particles is calculated by multiplying a value obtained by dividing the standard deviation of the particle diameter measured by the above method by the average particle diameter by 100.

In the solder particles, a flat portion may be formed on a part of the surface, and in this case, a surface other than the flat portion preferably has a spherical crown shape. That is, the solder particles may have a flat portion and a spherical crown-shaped curved surface. Examples of such solder particles include the solder particles 1 shown in FIG. 5. The ratio (A/B) of the diameter A of the flat portion to the diameter B of the solder particles 1 may be, for example, more than 0.01 and less than 1.0 (0.01<A/B<1.0) or may be 0.1 to 0.9. Since the solder particles have a flat portion, seating of the solder particles is improved and handling properties are improved. Specifically, when solder particles are disposed on an object to be connected by solder particles such as an electrode, due to the presence of the flat part, the solder particles are easily disposed at a predetermined position and there is an effect of preventing solder particles from moving from the predetermined position due to vibration, wind, an external force, static electricity or the like. In addition, when a member in which solder particles are disposed is tilted, for example, as compared with spherical solder particles having no flat part, there is an effect that solder particles do not easily move due to gravity.

When a quadrangle circumscribing a projected image of a solder particle is created by two pairs of parallel lines and distances between opposite sides are set as X and Y (where Y<X), the ratio (Y/X) of Y to X may be more than 0.8 and less than 1.0 (0.8<Y/X<1.0) or may be 0.9 or more and less than 1.0. Such solder particles can be particles closer to true spheres. According to the above production method of the present embodiment, such solder particles can be easily obtained. Since the solder particles are close to true spheres, for example, when a plurality of electrodes that face each other are electrically connected via the solder particles, the contact between the solder particles and the electrodes is less likely to be uneven, and a stable connection tends to be obtained. In addition, when a conductive film or resin in which solder particles are dispersed in a resin material is produced, high dispersibility is obtained and dispersion stability during production tends to be obtained. In addition, in a case of a film or paste in which solder particles are dispersed in a resin material is used for connection between electrodes, even if the solder particles rotate in the resin, when the solder particles have a spherical shape, projected areas of the solder particles are close to each other when viewed in a projected image. Therefore, a stable electrical connection with little variation during connection of electrodes tends to be obtained.

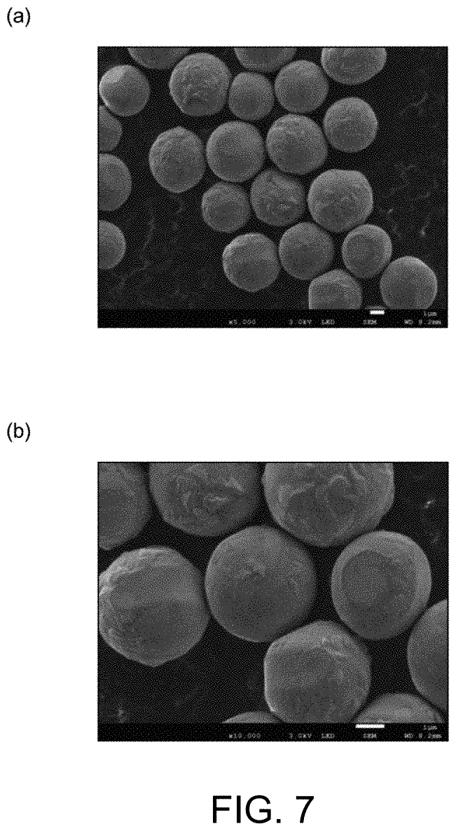

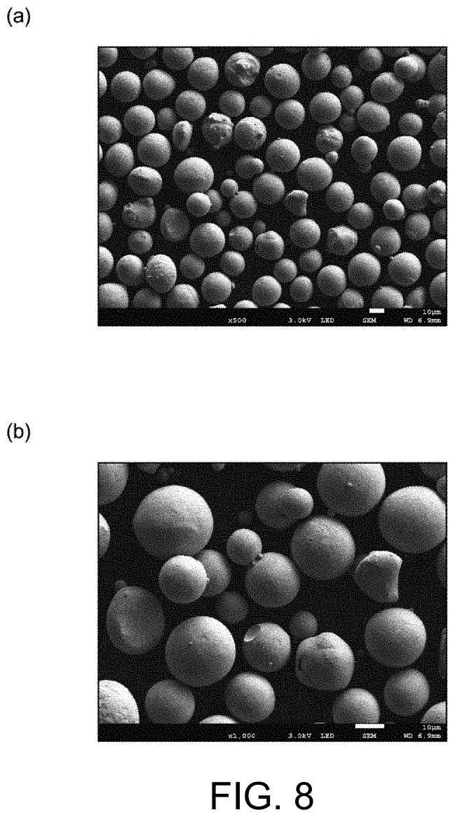

FIG. 6 is a diagram showing distances X and Y between opposite sides (where Y<X) when a quadrangle circumscribing a projected image of a solder particle is created by two pairs of parallel lines. For example, an arbitrary particle is observed under a scanning electron microscope and a projected image is obtained. Two pairs of parallel lines are drawn on the obtained projected image, one pair of parallel lines are arranged at a position at which the distance between the parallel lines is a minimum, the other pair of parallel lines are arranged at a position at which the distance between the parallel lines is a maximum, and Y/X of the particles is obtained. This operation is performed on 300 solder particles, an average value is calculated, and the Y/X of solder particles is obtained.

The solder particles may contain tin or a tin alloy. Regarding the tin alloy, for example, In—Sn alloys, In—Sn—Ag alloys, Sn—Au alloys, Sn—Bi alloys, Sn—Bi—Ag alloys, Sn—Ag—Cu alloys, and Sn—Cu alloys can be used. Specific examples of these tin alloys include the following examples.
In—Sn (In 52 mass %, Bi 48 mass %, melting point of 118° C.)
In—Sn—Ag (In 20 mass %, Sn 77.2 mass %, Ag 2.8 mass %, melting point of 175° C.)
Sn—Bi (Sn 43 mass %, Bi 57 mass %, melting point of 138° C.)
Sn—Bi—Ag (Sn 42 mass %, Bi 57 mass %, Ag 1 mass %, melting point of 139° C.)
Sn—Ag—Cu (Sn 96.5 mass %, Ag 3 mass %, Cu 0.5 mass %, melting point of 217° C.)
Sn—Cu (Sn 99.3 mass %, Cu 0.7 mass %, melting point of 227° C.)
Sn—Au (Sn 21.0 mass %, Au 79.0 mass %, melting point of 278° C.)

The solder particles may contain indium or an indium alloy. Regarding the indium alloy, for example, In—Bi alloys and In—Ag alloys can be used. Specific examples of these indium alloys include the following examples.
In—Bi (In 66.3 mass %, Bi 33.7 mass %, melting point of 72° C.)
In—Bi (In 33.0 mass %, Bi 67.0 mass %, melting point of 109° C.)
In—Ag (In 97.0 mass %, Ag 3.0 mass %, melting point of 145° C.)

The tin alloy or indium alloy can be selected according to applications of the solder particles (temperature during use). For example, when solder particles are used for fusion at a low temperature, In—Sn alloys and Sn—Bi alloys may be used, and in this case, solder particles can be fused at 150° C. or lower. When a material having a high melting point such as Sn—Ag—Cu alloys and Sn—Cu alloys is used, it is possible to maintain high reliability even after being left at a high temperature.

The solder particles may contain at least one selected from among Ag, Cu, Ni, Bi, Zn, Pd, Pb, Au, P and B. Among these elements, Ag or Cu may be contained in consideration of the following aspect. That is, when the solder particles contain Ag or Cu, the melting point of the solder particles can be lowered to about 220° C. and the bond strength with respect to an electrode is further improved, and thus more favorable conduction reliability is easily obtained.

The Cu content of the solder particles is, for example, 0.05 to 10 mass %, and may be 0.1 to 5 mass % or 0.2 to 3 mass %. When the Cu content is 0.05 mass % or more, more favorable solder connection reliability is easily achieved. In addition, when the Cu content is 10 mass % or less, solder particles having a low melting point and excellent wettability are easily obtained, and as a result, the reliability of connection of the bonding part to the solder particles tends to be favorable.

The Ag content of the solder particles is, for example, 0.05 to 10 mass %, and may be 0.1 to 5 mass % or 0.2 to 3 mass %. When the Ag content is 0.05 mass % or more, more favorable solder connection reliability is easily achieved. In addition, when the Ag content is 10 mass % or less, solder particles having a low melting point and excellent wettability are easily obtained, and as a result, the reliability of connection of the bonding part to the solder particles tends to be favorable.

The applications of the solder particles are not particularly limited, and for example, the solder particles can be suitably used as conductive particles for an anisotropic conductive material. In addition, the solder particles can be suitably used for applications such as electrically connecting electrodes in a ball grid array connection method (BGA connection) that is widely used for mounting a semiconductor integrated circuit and applications such as sealing components such as a microelectro mechanical system (MEMS) and pipe sealing, brazing, and height and clearance control spacers. That is, the solder particles can be used for general applications in which conventional solder is used.

While preferred embodiments of the present invention have been described above, the present invention is not limited to the above embodiments.

### EXAMPLES

The present invention will be described below in more detail with reference to examples, but the present invention is not limited to these examples.

### Example 1

### (Step a1) Classification of Solder Fine Particles

100 g of Sn—Bi solder fine particles (Type 8 commercially available from 5N Plus, a melting point of 139° C.) were immersed in distilled water and ultrasonically dispersed and then left, and the solder fine particles suspended in the supernatant were collected. This operation was repeated, and 10 g of the solder fine particles were collected. The average particle diameter of the obtained solder fine particles was 1.0 μm, and the C.V. value was 42%.

### (Step b1) Disposition in Base Material

A base material (polyimide film, a thickness of 100 μm) having a plurality of recesses with an opening diameter of 1.2 μmφ, a bottom diameter of 1.0 μmφ, and a depth of 1.0 μm (when the opening part was viewed from the top, the bottom diameter of 1.0 μmφ corresponded to the opening diameter of 1.2 μmφ at the center) was prepared. The plurality of recesses were regularly arranged at intervals of 1.0 μm. The solder fine particles (with an average particle diameter of 1.0 μm and a C.V. value of 42%) obtained in Step a were disposed in the recesses of the base material. Here, the surface side on which the recesses of the base material were formed was rubbed with a fine adhesive roller, excess solder fine particles were removed, and a base material in which the solder fine particles were disposed only in the recesses was obtained.

### (Step c1) Formation of Solder Particles

The base material in which the solder fine particles were disposed in the recesses in Step b1 was put into a hydrogen reduction furnace (vacuum soldering device commercially available from Shinko Seiki Co., Ltd.), the furnace was evacuated, hydrogen gas was introduced into the furnace, and the inside of the furnace was filled with hydrogen. Then, the temperature in the furnace was kept at 280° C. for 20 minutes, the furnace was then evacuated again, nitrogen was introduced to return to atmospheric pressure, the temperature in the furnace was then lowered to room temperature, and thereby solder particles were formed.

### (Step d1) Collection of Solder Particles

When the base material that had undergone Step c1 was tapped from the back side of the recess, the solder particles were collected from the recess. The obtained solder particles were evaluated according to the following method.

### (Evaluation of Solder Particles)

The obtained solder particles were placed on a conductive tape fixed to a surface of a pedestal for SEM observation, the pedestal for SEM observation was tapped on a stainless steel plate with a thickness of 5 mm, and the solder particles spread evenly on the conductive tape. Then, compressed nitrogen gas was sprayed onto the surface of the conductive tape and the solder particles were fixed as a single layer on the conductive tape. The diameters of 300 solder particles were measured using the SEM, and the average particle diameter and the C.V. value were calculated. The results are shown in Table 2.

### Examples 2 to 12

Solder particles were produced, collected and evaluated in the same manner as in Example 1 except that the size of the recess was changed as shown in Table 1. The results are shown in Table 2.

### Example 13

Solder particles were produced, collected and evaluated in the same manner as in Example 1 except that the following Step c2 was performed in place of Step c1. The results are shown in Table 2.

### (Step c2) Formation of Solder Particles

The base material in which the solder fine particles were disposed in the recesses in Step b1 was put into a hydrogen radical reduction furnace (plasma reflow device commercially available from Shinko Seiki Co., Ltd.), the furnace was evacuated, hydrogen gas was introduced into the furnace, and the inside of the furnace was filled with hydrogen gas. Then, the temperature in the furnace was adjusted to 120° C. and hydrogen radicals were emitted for 5 minutes. Then, hydrogen gas in the furnace was removed by evacuation, heating was performed to 170° C., nitrogen was then introduced into the furnace to return to atmospheric pressure, the temperature in the furnace was then lowered to room temperature, and thereby solder particles were formed.

### Examples 14 to 24

Solder particles were produced, collected and evaluated in the same manner as in Example 13 except that the size of the recess was changed as shown in Table 1. The results are shown in Table 2.

### Example 25

Solder particles were produced, collected and evaluated in the same manner as in Example 1 except that the following Step c3 was performed in place of Step c 1. The results are shown in Table 2.

### (Step c3) Formation of Solder Particles

The base material in which the solder fine particles were disposed in the recesses in Step b1 was put into a formic acid reduction furnace, the furnace was evacuated, a formic acid gas was then introduced into the furnace, and the inside of the furnace was filled with a formic acid gas. Then, the temperature in the furnace was adjusted to 130° C. and maintained for 5 minutes. Then, the formic acid gas in the furnace was removed by evacuation, heating was performed to 180° C., nitrogen was then introduced into the furnace to return to atmospheric pressure, the temperature in the furnace was then lowered to room temperature, and thereby solder particles were formed.

### Examples 26 to 36

Solder particles were produced, collected and evaluated in the same manner as in Example 25 except that the size of the recess was changed as shown in Table 1. The results are shown in Table 2.

### Example 37

Solder particles were produced, collected and evaluated in the same manner as in Example 1 except that the following Step c4 was performed in place of Step c1. The results are shown in Table 2.

### (Step c4) Formation of Solder Particles

The base material in which the solder fine particles were disposed in the recesses in Step b1 was put into a formic acid conveyor reflow furnace (1913MK commercially available from Heller Industries, Inc.), and caused to pass through a nitrogen zone, a nitrogen and formic acid gas mixture zone, and a nitrogen zone consecutively while it was transported by the conveyor. The material was caused to pass through the nitrogen and formic acid gas mixture zone in 5 minutes, and thereby solder particles were formed.

### Examples 38 to 48

Solder particles were produced, collected and evaluated in the same manner as in Example 37 except that the size of the recess was changed as shown in Table 1. The results are shown in Table 2.

TABLE 1

| | | Example | Example | Example | Example | Example | Example | Example | Example | Example | Example | Example | Example |
|---|---|---|---|---|---|---|---|---|---|---|---|---|---|
| | | 1 | 2 | 3 | 4 | 5 | 6 | 7 | 8 | 9 | 10 | 11 | 12 |
| Opening | μm | 1.2 | 1.7 | 2.3 | 3.3 | 4.3 | 5.3 | 6.3 | 11 | 15 | 26 | 33 | 40 |
| diameter | | | | | | | | | | | | | |
| Bottom | μm | 1 | 1.5 | 2 | 3 | 4 | 5 | 6 | 10 | 15 | 26 | 33 | 40 |
| diameter | | | | | | | | | | | | | |
| Depth | μm | 1 | 1.5 | 2 | 3 | 4 | 5 | 6 | 10 | 15 | 15 | 15 | 15 |
| Interval | μm | 1 | 1.5 | 2 | 3 | 4 | 5 | 6 | 10 | 15 | 20 | 25 | 30 |
| | | Example | Example | Example | Example | Example | Example | Example | Example | Example | Example | Example | Example |
| | | 13 | 14 | 15 | 16 | 17 | 18 | 19 | 20 | 21 | 22 | 23 | 24 |
| Opening | μm | 1.2 | 1.7 | 2.3 | 3.3 | 4.3 | 5.3 | 6.3 | 11 | 15 | 26 | 33 | 40 |
| diameter | | | | | | | | | | | | | |
| Bottom | μm | 1 | 1.5 | 2 | 3 | 4 | 5 | 6 | 10 | 15 | 26 | 33 | 40 |
| diameter | | | | | | | | | | | | | |
| Depth | μm | 1 | 1.5 | 2 | 3 | 4 | 5 | 6 | 10 | 15 | 15 | 15 | 15 |
| Interval | μm | 1 | 1.5 | 2 | 3 | 4 | 5 | 6 | 10 | 15 | 20 | 25 | 30 |
| | | Example | Example | Example | Example | Example | Example | Example | Example | Example | Example | Example | Example |
| | | 25 | 26 | 27 | 28 | 29 | 30 | 31 | 32 | 33 | 34 | 35 | 36 |
| Opening | μm | 1.2 | 1.7 | 2.3 | 3.3 | 4.3 | 5.3 | 6.3 | 11 | 15 | 26 | 33 | 40 |
| diameter | | | | | | | | | | | | | |
| Bottom | μm | 1 | 1.5 | 2 | 3 | 4 | 5 | 6 | 10 | 15 | 26 | 33 | 40 |
| diameter | | | | | | | | | | | | | |
| Depth | μm | 1 | 1.5 | 2 | 3 | 4 | 5 | 6 | 10 | 15 | 15 | 15 | 15 |
| Interval | μm | 1 | 1.5 | 2 | 3 | 4 | 5 | 6 | 10 | 15 | 20 | 25 | 30 |
| | | Example | Example | Example | Example | Example | Example | Example | Example | Example | Example | Example | Example |
| | | 37 | 38 | 39 | 40 | 41 | 42 | 43 | 44 | 45 | 46 | 47 | 48 |
| Opening | μm | 1.2 | 1.7 | 2.3 | 3.3 | 4.3 | 5.3 | 6.3 | 11 | 15 | 26 | 33 | 40 |
| diameter | | | | | | | | | | | | | |
| Bottom | μm | 1 | 1.5 | 2 | 3 | 4 | 5 | 6 | 10 | 15 | 26 | 33 | 40 |
| diameter | | | | | | | | | | | | | |
| Depth | μm | 1 | 1.5 | 2 | 3 | 4 | 5 | 6 | 10 | 15 | 15 | 15 | 15 |
| Interval | μm | 1 | 1.5 | 2 | 3 | 4 | 5 | 6 | 10 | 15 | 20 | 25 | 30 |

TABLE 2

| | | Example | Example | Example | Example | Example | Example | Example | Example | Example | Example | Example | Example |
|---|---|---|---|---|---|---|---|---|---|---|---|---|---|
| | | 1 | 2 | 3 | 4 | 5 | 6 | 7 | 8 | 9 | 10 | 11 | 12 |
| Average | μm | 1 | 1.5 | 2 | 3 | 4 | 5 | 6 | 10 | 15 | 20 | 25 | 30 |
| particle | | | | | | | | | | | | | |
| diameter | | | | | | | | | | | | | |
| C.V. value | % | 19 | 16 | 14 | 10 | 7.9 | 7.8 | 6.6 | 5.2 | 4.4 | 4.2 | 3.9 | 3.3 |
| | | Example | Example | Example | Example | Example | Example | Example | Example | Example | Example | Example | Example |
| | | 13 | 14 | 15 | 16 | 17 | 18 | 19 | 20 | 21 | 22 | 23 | 24 |
| Average | μm | 0.9 | 1.3 | 1.8 | 2.7 | 3.8 | 4.8 | 6 | 9 | 14 | 19 | 24 | 29 |
| particle | | | | | | | | | | | | | |
| diameter | | | | | | | | | | | | | |
| C.V. value | % | 10 | 10 | 9.6 | 9.3 | 7.9 | 7.8 | 6.6 | 5.2 | 4.4 | 4.2 | 3.9 | 3.3 |
| | | Example | Example | Example | Example | Example | Example | Example | Example | Example | Example | Example | Example |
| | | 25 | 26 | 27 | 28 | 29 | 30 | 31 | 32 | 33 | 34 | 35 | 36 |
| Average | μm | 1 | 1.5 | 2 | 3 | 4 | 5 | 6 | 10 | 15 | 20 | 25 | 30 |
| particle | | | | | | | | | | | | | |
| diameter | | | | | | | | | | | | | |
| C.V. value | % | 16 | 15 | 12 | 9.5 | 7.9 | 7.4 | 6.6 | 5.2 | 4.4 | 4.2 | 3.9 | 3.3 |
| | | Example | Example | Example | Example | Example | Example | Example | Example | Example | Example | Example | Example |
| | | 37 | 38 | 39 | 40 | 41 | 42 | 43 | 44 | 45 | 46 | 47 | 48 |
| Average | μm | 1 | 1.5 | 2 | 3 | 4 | 5 | 6 | 10 | 15 | 20 | 25 | 30 |
| particle | | | | | | | | | | | | | |
| diameter | | | | | | | | | | | | | |
| C.V. value | % | 11 | 10 | 9.9 | 9.5 | 7.8 | 7.4 | 6.4 | 5.3 | 4.5 | 4.4 | 4.0 | 3.9 |

### Production Example 1

### (A) Production of Anisotropic Conductive Film

### (Step e1) Production of Flux-Coated Solder Particles

Solder particles were produced in the same method as in Example 13. 200 g of the obtained solder particles, 40 g of adipic acid, and 70 g of acetone were weighed out in a three-neck flask, and 0.3 g of dibutyl tin oxide that catalysts a dehydration condensation reaction between hydroxy groups on the surface of the solder particles and carboxylic groups of adipic acid was then added thereto and reacted at 60° C. for 4 hours. Then, the solder particles were collected by filtration. The collected solder particles, 50 g of adipic acid, 200 g of toluene, and 0.3 g of para-toluene sulfonic acid were weighed out in a three-neck flask and reacted at 120° C. for 3 hours while evacuating and refluxing. In this case, the reaction was performed while removing water generated by dehydration condensation using a Dean-Stark extraction device. Then, the solder particles were collected by filtration, washed with hexane and dried. The dried solder particles were crushed by an airflow type crusher, passed through a mesh with an ultrasonic sieve, and thereby flux-coated solder particles were obtained.

### (Step f1) Disposition of Flux-Coated Solder Particles

A transfer mold (polyimide film, a thickness of 100 μm) having a plurality of recesses with an opening diameter of 1.2 μmφ, a bottom diameter of 1.0 μmφ, and a depth of 1.0 μm (when the opening part was viewed from the top, the bottom diameter of 1.0 μmφ corresponded to the opening diameter of 1.2 μmφ at the center) was prepared. Here, the plurality of recesses were regularly arranged at intervals of 1.0 μm. The flux-coated solder particles obtained in Step e1 were disposed in the recesses of the transfer mold.

### (Step g1) Production of Adhesive Film

100 g of a phenoxy resin (product name “PKHC” commercially available from Union Carbide Corporation) and 75 g of an acrylic rubber (a copolymer containing 40 parts by mass of butyl acrylate, 30 parts by mass of ethyl acrylate, 30 parts by mass of acrylonitrile, and 3 parts by mass of glycidyl methacrylate, molecular weight: 850,000) were dissolved in 400 g of ethyl acetate to obtain a solution. 300 g of a liquid epoxy resin containing a microcapsule type latent curing agent (epoxy equivalent 185, product name “Novacure HX-3941” commercially available from Asahi Kasei Corporation) was added to the solution, and the mixture was stirred to obtain an adhesive solution. The obtained adhesive solution was applied to a separator (silicone-treated polyethylene terephthalate film, a thickness of 40 μm) using a roll coater, and heated at 90° C. for 10 minutes and dried, and adhesive films (insulating resin films) having a thickness of 4 μm, 6 μm, 8 μm, 12 μm and 20 μm were prepared on the separator.

### (Step h1) Transfer of Flux-Coated Solder Particles

The adhesive film formed on the separator and the transfer mold in which the flux-coated solder particles were disposed in Step f1 were arranged to face each other, and the flux-coated solder particles were transferred to the adhesive film.

### (Step i1) Production of Anisotropic Conductive Film

The adhesive film produced in the same method as in Step g1 was brought into contact with a transfer surface of the adhesive film obtained in Step h1, and heated and pressurized at 50° C. and 0.1 MPa (1 kgf/cm²), and an anisotropic conductive film in which the flux-coated solder particles were disposed in layers in a cross-sectional view of the film was obtained. Here, 4 μm was superimposed for a film with a thickness of 4 μm, and similarly, 6 μm was superimposed for a film with a thickness of 6 μm, 8 μm was superimposed for a film with a thickness of 8 μm, 12 μm was superimposed for a film with a thickness of 12 μm, and 20 μm was superimposed for a film with a thickness of 20 μm, and anisotropic conductive films having a thickness of 8 μm, 12 μm, 16 μm, 24 μm and 40 μm were produced.

### (B) Production of Connection Structure

(Step j1) Preparation of Chip with Copper Bumps
Five types of chips with copper bumps (1.7 mm×1.7 mm, thickness: 0.5 mm) shown below were prepared.
Chip C1 . . . area 30 μm×30 μm, space 30 μm, height: 10 μm, number of bumps 362
Chip C2 . . . area 15 μm×15 μm, space 10 μm, height: 10 μm, number of bumps 362
Chip C3 . . . area 10 μm×10 μm, space 10 μm, height: 7 μm, number of bumps 362
Chip C4 . . . area 5 μm×5 μm, space 6 μm, height: 5 μm, number of bumps 362
Chip C5 . . . area 3 μm×3 μm, space 3 μm, height: 5 μm, number of bumps 362
   (Step k1) Preparation of Substrate with Copper Bumps

Five types of substrates with copper bumps (thickness: 0.7 mm) shown below were prepared.
Substrate D1 . . . area 30 μm×30 μm, space 30 μm, height: 10 μm, number of bumps 362
Substrate D2 . . . area 15 μm×15 μm, space 10 μm, height: 10 μm, number of bumps 362
Substrate D3 . . . area 10 μm×10 μm, space 10 μm, height: 7 μm, number of bumps 362
Substrate D4 . . . area 5 μm×5 μm, space 6 μm, height: 5 μm, number of bumps 362
Substrate D5 . . . area 3 μm×3 μm, space 3 μm, height: 5 μm, number of bumps 362

### (Step l1)

Next, using the anisotropic conductive film produced in Step i1, a chip with copper bumps (1.7 mm×1.7 mm, thickness: 0.5 mm) and a substrate with copper bumps (thickness: 0.7 mm) were connected according to the following procedures i) to iii) to obtain a connection structure.
i) A separator (silicone-treated polyethylene terephthalate film, a thickness of 40 μm) on one surface of the anisotropic conductive film (2 mmx 19 mm) was peeled off, and the anisotropic conductive film and the substrate with copper bumps were brought into contact with each other and bonded at 80° C. and 0.98 MPa (10 kgf/cm²).
ii) The separator was peeled off, and the bumps of the chip with copper bumps and the bumps of the substrate with copper bumps were aligned.
iii) Heating and pressurizing were performed from above the chip under conditions of 180° C., 40 gf/bump, and 30 seconds, and thus connection was performed. A total of seven types of connection structures according to (1) to (7) were produced by combining the following (1) to (7) “chip/anisotropic conductive film/substrate” (1) Chip C1/conductive film with a thickness of 40 μm/substrate D1
(2) Chip C1/conductive film with a thickness of 24 μm/substrate D1
(3) Chip C1/conductive film with a thickness of 16 μm/substrate D1
(4) Chip C2/conductive film with a thickness of 16 μm/substrate D2
(5) Chip C3/conductive film with a thickness of 12 μm/substrate D3
(6) Chip C4/conductive film with a thickness of 8 μm/substrate D4
(7) Chip C5/conductive film with a thickness of 8 μm/substrate D5

### Production Examples 2 to 12

An anisotropic conductive film and a connection structure were produced in the same method as in Production Example 1 except that the solder particles produced in the same method as in Examples 14 to 24 were used and a transfer mold having the same shape as the base material used in production of the solder particles of Examples 14 to 24 was used as a transfer mold.

### Comparative Production Example 1

An anisotropic conductive film and a connection structure were produced in the same method as in Production Example 1 except that Sn—Bi solder particles (“Type-4” commercially available from Mitsu Mining & Smelting Co., Ltd., an average particle diameter of 26 μm and a C.V. value of 25%) were used as solder particles.

### Comparative Production Example 2

A solder particles-containing anisotropic conductive paste containing the following components in the following parts by mass was produced.
(Polymer): 12 parts by mass
(Thermosetting compound): 29 parts by mass
(High dielectric constant curing agent): 20 parts by mass
(Thermosetting agent): 11.5 parts by mass
(Flux): 2 parts by mass
(Solder particles) 34 parts by mass

### (Polymer):

72 parts by mass of bisphenol F (containing 4,4′-methylene bisphenol, 2,4′-methylene bisphenol and 2,2′-methylene bisphenol at a mass ratio of 2:3:1), 70 parts by mass of 1,6-hexanediol diglycidyl ether, and 30 parts by mass of a bisphenol F type epoxy resin (“EPICLON EXA-830CRP” commercially available from DIC) were put into a three-neck flask and dissolved at 150° C. under a nitrogen flow. Then, 0.1 parts by mass of tetra n-butyl sulfonium bromide as an addition reaction catalyst for hydroxy groups and epoxy groups was added, and an addition polymerization reaction was performed at 150° C. for 6 hours under a nitrogen flow to obtain a reaction product (polymer).
(Thermosetting compound): resorcinol type epoxy compound, “EX-201” commercially available from Nagase ChemteX Corporation
(High dielectric constant curing agent): pentaerythritol tetrakis(3-mercaptobutyrate)
(Thermosetting agent): “Karenz MT PE1” commercially available from Showa Denko K.K.
(Flux): adipic acid, commercially available from Wako Pure Chemical Corporation

### (Solder Particles):

200 g of SnBi solder particles (“ST-3” commercially available from Mitsu Mining & Smelting Co., Ltd.), 40 g of adipic acid, and 70 g of acetone were weighed out in a three-neck flask, and 0.3 g of dibutyl tin oxide as a dehydration condensation catalyst for hydroxy groups on the surface of solder particle bodies and carboxylic groups of adipic acid was then added thereto and reacted at 60° C. for 4 hours. Then, the solder particles were collected by filtration. The collected solder particles, 50 g of adipic acid, 200 g of toluene, and 0.3 g of para-toluene sulfonic acid were weighed out in a three-neck flask, and reacted at 120° C. for 3 hours while evacuating and refluxing. In this case, the reaction was performed while removing water generated by dehydration condensation using a Dean-Stark extraction device. Then, the solder particles were collected by filtration, washed with hexane and dried. Then, the obtained solder particles were crushed with a ball mill. The average particle diameter of the obtained SnBi solder particles was 4 μm and the C.V. value was 32%.

A chip with copper bumps and a substrate with copper bumps were prepared in the same manner as in Production Example 1. The solder particles-containing anisotropic conductive paste was disposed above the substrate with copper bumps and the chip with copper bumps was additionally disposed thereon. The bumps of the chip with copper bumps and the bumps of the substrate with copper bumps were aligned, heating and pressurizing were performed from above the chip under conditions of 180° C., 4 gf/bump, and 30 seconds, and thus connection was performed. A total of seven types of connection structures according to (1) to (7) were produced by combining the following (1) to (7).
(1) Chip C1/solder particles-containing anisotropic conductive paste with a thickness of 40 μm (on copper bumps)/substrate D1,
(2) Chip C1/solder particles-containing anisotropic conductive paste with a thickness of 24 μm (on copper bumps)/substrate D1,
(3) Chip C 1/solder particles-containing anisotropic conductive paste with a thickness of 16 μm (on copper bumps)/substrate D1,
(4) Chip C2/solder particles-containing anisotropic conductive paste with a thickness of 16 μm (on copper bumps)/substrate D2,
(5) Chip C3/solder particles-containing anisotropic conductive paste with a thickness of 12 μm (on copper bumps)/substrate D3,
(6) Chip C4/solder particles-containing anisotropic conductive paste with a thickness of 8 μm (on copper bumps)/substrate D4, and
(7) Chip C5/solder particles-containing anisotropic conductive paste with a thickness of 8 μm (on copper bumps)/substrate D5 were connected in combination to obtain the following connection structures (1) to (7).

### [Evaluation of Connection Structure]

A conduction resistance test and an insulation resistance test were performed on a part of the obtained connection structure as follows.

### (Conduction Resistance Test-Moisture Absorption and Heat Resistance Test)

Regarding the conduction resistance between the chip with copper bumps (bumps)/the substrate with copper bumps (bumps), the initial value of the conduction resistance and the value after the moisture absorption and heat resistance test (being left under conditions of a temperature of 85° C. and a humidity of 85% for 100, 500, and 1,000 hours) were measured for 20 samples, and the average value thereof was calculated. The conduction resistance was evaluated from the obtained average value according to the following criteria. The results are shown in Table 3. Here, when the following criterion A or B was satisfied after the moisture absorption and heat resistance test was performed for 1,000 hours, the conduction resistance was evaluated as favorable.
A: Average value of the conduction resistance was less than 2 Ω
B: Average value of the conduction resistance was 2Ω or more and less than 5 Ω
C: Average value of the conduction resistance was 5Ω or more and less than 10 Ω
D: Average value of the conduction resistance was 10Ω or more and less than 20 Ω
E: Average value of the conduction resistance was 20Ω or more

### (Conduction Resistance Test-High Temperature Endurance Test)

Regarding the conduction resistance between the chip with copper bumps (bumps)/the substrate with copper bumps (bumps), the samples were measured before being left at a high temperature and after the high temperature endurance test (being left under conditions of a temperature of 100° C. for 100 hours, 500 hours, and 1,000 hours). Here, after being left at a high temperature, a drop impact was applied and the conduction resistance of the sample after the drop impact was measured. For the drop impact, the connection structure was screwed and fixed to a metal plate and dropped from a height of 50 cm. After being dropped, the DC resistance value was measured at solder bonding parts (4 points) on a chip corner in which the impact was greatest, and evaluation was performed assuming that breakage had occurred when the measured value increased to 5 or more times the initial resistance. Here, the measurement was performed at 4 points for 20 samples, for a total of 80 points. The results are shown in Table 4. When the following criterion A or B was satisfied after 20 drops, the solder connection reliability was evaluated as favorable.
A: After 20 drops, no solder connecting parts having a value increased to 5 or more times the initial resistance was observed at any of the 80 points.
B: After 20 drops, a solder connecting part having a value increased to 5 or more times the initial resistance was observed at 1 point or more and 5 points or less.
C: After 20 drops, a solder connecting part having a value increased to 5 or more times the initial resistance was observed at 6 points or more and 20 points or less.
D: After 20 drops, a solder connecting part having a value increased to 5 or more times the initial resistance was observed at 21 points or more.

### (Insulation Resistance Test)

Regarding the insulation resistance between chip electrodes, the initial value of the insulation resistance and the value after the migration test (being left under conditions of a temperature of 60° C., a humidity of 90%, and 20 V application for 100 hours, 500 hours, 1,000 hours) were measured for 20 samples, and a proportion of samples having an insulation resistance value of 10⁹Ω or more with respect to all 20 samples was calculated. The insulation resistance was evaluated from the obtained proportion according to the following criteria. The results are shown in Table 5. Here, when the following criterion A or B was satisfied after the moisture absorption and heat resistance test was performed for 1,000 hours, the insulation resistance was evaluated as favorable.
A: Proportion with an insulation resistance value of 10⁹Ω or more was 100%
B: Proportion with an insulation resistance value of 10⁹Ω or more was 90% or more and less than 100%
C: Proportion with an insulation resistance value of 10⁹Ω or more was 80% or more and less than 90%
D: Proportion with an insulation resistance value of 10⁹Ω or more was 50% or more and less than 80%
E: Proportion with an insulation resistance value of 10⁹Ω or more was less than 50%

TABLE 3

| | | | | Production | Production | Production | Production | Production | Production | Production |
|---|---|---|---|---|---|---|---|---|---|---|
| | | | | Example | Example | Example | Example | Example | Example | Example |
| | | | | 1 | 2 | 3 | 4 | 5 | 6 | 7 |
| | | Connection | | Example | Example | Example | Example | Example | Example | Example |
| | | structure | Solder particles | 13 | 14 | 15 | 16 | 17 | 18 | 19 |
| Conduction | Moisture | (1) | Initial | | | | | | | |
| resistance | absorption | | After 100 hours | | | | | | | |
| | and heat | | After 500 hours | | | | | | | |
| | resistance | | After 1,000 hours | | | | | | | |
| | test | (2) | Initial | | | | | | | |
| | | | After 100 hours | | | | | | | |
| | | | After 500 hours | | | | | | | |
| | | | After 1,000 hours | | | | | | | |
| | | (3) | Initial | | | A | A | A | A | A |
| | | | After 100 hours | | | B | B | A | A | A |
| | | | After 500 hours | | | B | B | A | A | A |
| | | | After 1,000 hours | | | B | B | A | A | A |
| | | (4) | Initial | | | A | A | A | A | A |
| | | | After 100 hours | | | B | A | A | A | A |
| | | | After 500 hours | | | B | A | A | A | A |
| | | | After 1,000 hours | | | B | A | A | A | A |
| | | (5) | Initial | A | A | A | A | A | A | A |
| | | | After 100 hours | B | B | A | A | A | A | A |
| | | | After 500 hours | B | B | A | A | A | A | A |
| | | | After 1,000 hours | B | B | A | A | A | A | A |
| | | (6) | Initial | B | A | A | A | A | A | A |
| | | | After 100 hours | B | B | A | A | A | A | A |
| | | | After 500 hours | B | B | A | A | A | A | A |
| | | | After 1,000 hours | B | B | A | A | A | A | A |
| | | (7) | Initial | B | A | A | A | A | A | A |
| | | | After 100 hours | B | A | A | A | A | A | A |
| | | | After 500 hours | B | A | A | A | A | A | A |
| | | | After 1,000 hours | B | A | A | A | A | A | A |
| | | | | Production | Production | Production | Production | Production | Compar- | Compar- |
| | | | | Example | Example | Example | Example | Example | ative | ative |
| | | | | 8 | 9 | 10 | 11 | 12 | Production | Production |
| | | Connection | | Example | Example | Example | Example | Example | Example | Example |
| | | structure | Solder particles | 20 | 21 | 22 | 23 | 24 | 1 | 2 |
| Conduction | Moisture | (1) | Initial | | | A | A | A | A | |
| resistance | absorption | | After 100 hours | | | A | A | A | A | |
| | and heat | | After 500 hours | | | A | A | A | A | |
| | resistance | | After 1,000 hours | | | A | A | A | A | |
| | test | (2) | Initial | A | A | A | A | | A | |
| | | | After 100 hours | B | A | A | A | | A | |
| | | | After 500 hours | B | A | A | A | | A | |
| | | | After 1,000 hours | B | A | A | A | | A | |
| | | (3) | Initial | A | A | | | | | A |
| | | | After 100 hours | A | A | | | | | B |
| | | | After 500 hours | A | A | | | | | B |
| | | | After 1,000 hours | A | A | | | | | B |
| | | (4) | Initial | A | A | | | | | A |
| | | | After 100 hours | A | A | | | | | B |
| | | | After 500 hours | A | A | | | | | B |
| | | | After 1,000 hours | A | A | | | | | B |
| | | (5) | Initial | A | | | | | | A |
| | | | After 100 hours | A | | | | | | B |
| | | | After 500 hours | A | | | | | | B |
| | | | After 1,000 hours | A | | | | | | C |
| | | (6) | Initial | | | | | | | A |
| | | | After 100 hours | | | | | | | B |
| | | | After 500 hours | | | | | | | C |
| | | | After 1,000 hours | | | | | | | C |
| | | (7) | Initial | | | | | | | C |
| | | | After 100 hours | | | | | | | C |
| | | | After 500 hours | | | | | | | D |
| | | | After 1,000 hours | | | | | | | E |

TABLE 4

| | | | | Production | Production | Production | Production | Production | Production | Production |
|---|---|---|---|---|---|---|---|---|---|---|
| | | | | Example | Example | Example | Example | Example | Example | Example |
| | | | | 1 | 2 | 3 | 4 | 5 | 6 | 7 |
| | | Connection | | Example | Example | Example | Example | Example | Example | Example |
| | | structure | Solder particles | 13 | 14 | 15 | 16 | 17 | 18 | 19 |
| Conduction | High | (1) | Initial | | | | | | | |
| resistance | temperature | | After 100 hours | | | | | | | |
| | endurance | | After 500 hours | | | | | | | |
| | test | | After 1,000 hours | | | | | | | |
| | | (3) | Initial | | | A | A | A | A | A |
| | | | After 100 hours | | | B | A | A | A | A |
| | | | After 500 hours | | | B | A | A | A | A |
| | | | After 1,000 hours | | | B | A | A | A | A |
| | | (6) | Initial | A | A | A | A | A | A | A |
| | | | After 100 hours | B | A | A | A | A | A | A |
| | | | After 500 hours | B | A | A | A | A | A | A |
| | | | After 1,000 hours | B | A | A | A | A | A | A |
| | | | | Production | Production | Production | Production | Production | Compar- | Compar- |
| | | | | Example | Example | Example | Example | Example | ative | ative |
| | | | | 8 | 9 | 10 | 11 | 12 | Production | Production |
| | | Connection | | Example | Example | Example | Example | Example | Example | Example |
| | | structure | Solder particles | 20 | 21 | 22 | 23 | 24 | 1 | 2 |
| Conduction | High | (1) | Initial | | | A | A | A | A | |
| resistance | temperature | | After 100 hours | | | A | A | A | A | |
| | endurance | | After 500 hours | | | A | A | A | A | |
| | test | | After 1,000 hours | | | A | A | A | A | |
| | | (3) | Initial | A | A | | | | | A |
| | | | After 100 hours | A | A | | | | | B |
| | | | After 500 hours | A | A | | | | | B |
| | | | After 1,000 hours | A | A | | | | | B |
| | | (6) | Initial | | | | | | | B |
| | | | After 100 hours | | | | | | | C |
| | | | After 500 hours | | | | | | | D |
| | | | After 1,000 hours | | | | | | | D |

TABLE 5

| | | | | Production | Production | Production | Production | Production | Production | Production |
|---|---|---|---|---|---|---|---|---|---|---|
| | | | | Example | Example | Example | Example | Example | Example | Example |
| | | | | 1 | 2 | 3 | 4 | 5 | 6 | 7 |
| | | Connection | Solder | Example | Example | Example | Example | Example | Example | Example |
| | | structure | particles | 13 | 14 | 15 | 16 | 17 | 18 | 19 |
| Insulation | Moisture | (1) | Initial | | | | | | | |
| resistance | absorption | | After 100 hours | | | | | | | |
| | and heat | | After 500 hours | | | | | | | |
| | resistance | | After 1,000 hours | | | | | | | |
| | test | (2) | Initial | | | | | | | |
| | | | After 100 hours | | | | | | | |
| | | | After 500 hours | | | | | | | |
| | | | After 1,000 hours | | | | | | | |
| | | (3) | Initial | | | A | A | A | A | A |
| | | | After 100 hours | | | A | A | A | A | A |
| | | | After 500 hours | | | A | A | A | A | A |
| | | | After 1,000 hours | | | A | A | A | A | A |
| | | (4) | Initial | | | A | A | A | A | A |
| | | | After 100 hours | | | A | A | A | A | A |
| | | | After 500 hours | | | A | A | A | A | A |
| | | | After 1,000 hours | | | A | A | A | A | A |
| | | (5) | Initial | A | A | A | A | A | A | A |
| | | | After 100 hours | A | A | A | A | A | A | A |
| | | | After 500 hours | A | A | A | A | A | A | A |
| | | | After 1,000 hours | A | A | A | A | A | A | A |
| | | (6) | Initial | A | A | A | A | A | A | A |
| | | | After 100 hours | A | A | A | A | A | B | |
| | | | After 500 hours | A | A | A | A | A | B | |
| | | | After 1,000 hours | A | A | A | A | A | B | |
| | | (7) | Initial | A | A | A | A | | | |
| | | | After 100 hours | A | A | A | B | | | |
| | | | After 500 hours | A | A | A | B | | | |
| | | | After 1,000 hours | A | A | A | B | | | |
| | | | | Production | Production | Production | Production | Production | Compar- | Compar- |
| | | | | Example | Example | Example | Example | Example | ative | ative |
| | | | | 8 | 9 | 10 | 11 | 12 | Production | Production |
| | | Connection | Solder | Example | Example | Example | Example | Example | Example | Example |
| | | structure | particles | 20 | 21 | 22 | 23 | 24 | 1 | 2 |
| Insulation | Moisture | (1) | Initial | | | A | A | A | C | |
| resistance | absorption | | After 100 hours | | | A | B | B | C | |
| | and heat | | After 500 hours | | | A | B | B | D | |
| | resistance | | After 1,000 hours | | | A | B | B | D | |
| | test | (2) | Initial | A | A | A | A | | D | |
| | | | After 100 hours | A | A | A | B | | D | |
| | | | After 500 hours | A | A | A | B | | D | |
| | | | After 1,000 hours | A | A | A | B | | E | |
| | | (3) | Initial | A | A | | | | | C |
| | | | After 100 hours | A | A | | | | | C |
| | | | After 500 hours | A | A | | | | | C |
| | | | After 1,000 hours | A | A | | | | | D |
| | | (4) | Initial | A | A | | | | | D |
| | | | After 100 hours | A | B | | | | | D |
| | | | After 500 hours | A | B | | | | | E |
| | | | After 1,000 hours | A | B | | | | | E |
| | | (5) | Initial | A | | | | | | D |
| | | | After 100 hours | B | | | | | | D |
| | | | After 500 hours | B | | | | | | D |
| | | | After 1,000 hours | B | | | | | | E |
| | | (6) | Initial | | | | | | | E |
| | | | After 100 hours | | | | | | | E |
| | | | After 500 hours | | | | | | | E |
| | | | After 1,000 hours | | | | | | | E |
| | | (7) | Initial | | | | | | | E |
| | | | After 100 hours | | | | | | | E |
| | | | After 500 hours | | | | | | | E |
| | | | After 1,000 hours | | | | | | | E |

### <Evaluation of Solder Particles>

(Step e1) to (Step h1) were performed in the same manner as in Production Example 1 except that the solder particles obtained in Example 1 were used, and an adhesive film to which the solder particles were transferred was obtained. This adhesive film was cut to 10 cm×10 cm, Pt sputtering was performed on a surface on which the solder particles were disposed, and observation was then performed using an SEM. 300 solder particles were observed, the average diameter B (average particle diameter) of the solder particles, the average diameter A of the flat portion, the roundness, and A/B and Y/X were calculated. In addition, the same measurement was performed using the solder particles of Examples 2 to 12. The results are shown in Table 6. Roundness: a ratio r/R of radii of two concentric circles (a radius r of a minimum circumscribed circle, and a radius R of a maximum inscribed circle) of solder particles A/B: a ratio of the diameter A of the flat portion to the diameter B of solder particles Y/X: a ratio of Y to X when distances between opposite sides were set as X and Y (where Y<X) and a quadrangle circumscribing a projected image of a solder particle was created by two pairs of parallel lines

TABLE 6

| | | Example | Example | Example | Example | Example | Example | Example | Example | Example | Example | Example | Example |
|---|---|---|---|---|---|---|---|---|---|---|---|---|---|
| | | 1 | 2 | 3 | 4 | 5 | 6 | 7 | 8 | 9 | 10 | 11 | 12 |
| Average | μm | 1 | 1.5 | 2 | 3 | 4 | 5 | 6 | 10 | 15 | 20 | 25 | 30 |
| diameter B | | | | | | | | | | | | | |
| Diameter A of | μm | 0.2 | 0.3 | 0.4 | 0.5 | 0.6 | 0.7 | 0.8 | 1.4 | 2.0 | 3.6 | 4.5 | 5.1 |
| flat portion | | | | | | | | | | | | | |
| Roundness | | 0.93 | 0.93 | 0.93 | 0.93 | 0.93 | 0.93 | 0.93 | 0.93 | 0.93 | 0.93 | 0.93 | 0.93 |
| A/B | | 0.2 | 0.2 | 0.2 | 0.17 | 0.15 | 0.14 | 0.13 | 0.14 | 0.13 | 0.18 | 0.18 | 0.17 |
| Y/X | | 0.94 | 0.92 | 0.92 | 0.93 | 0.93 | 0.91 | 0.91 | 0.92 | 0.9 | 0.87 | 0.84 | 0.82 |

Here, (a) of FIG. 7 and (b) of FIG. 7 are diagrams showing an SEM image of the solder particles formed in Example 17, and (a) of FIG. 8 and (b) of FIG. 8 are diagrams showing an SEM image of the solder particles used in Comparative Production Example 1.

### Example 49

Solder particles were produced, collected and evaluated in the same manner as in Example 1 except that, in Step b1, a base material having a cross-sectional shape (a recess shape similar to that of (b) of FIG. 2) shown in FIG. 9, that is, having a plurality of recesses with a bottom diameter a of 0.6 μm, an opening diameter b1 of 1.0 μm, and an opening diameter b2 of 1.2 μm (when the opening part was viewed from the top, the bottom diameter a of 1.0 μmφ corresponded to the opening diameter b2 of 1.2 μmφ at the center) was used, and the following Step c2 was performed in place of Step c1. The results are shown in Table 8.

### (Step c2) Formation of Solder Particles

The base material in which the solder fine particles were disposed in the recesses in Step b1 was put into a hydrogen radical reduction furnace (plasma reflow device commercially available from Shinko Seiki Co., Ltd.), the furnace was evacuated, hydrogen gas was introduced into the furnace, and the inside of the furnace was filled with hydrogen gas. Then, the temperature in the furnace was adjusted to 120° C. and hydrogen radicals were emitted for 5 minutes. Then, hydrogen gas in the furnace was removed by evacuation, heating was performed to 170° C., nitrogen was then introduced into the furnace to return to atmospheric pressure, the temperature in the furnace was then lowered to room temperature, and thereby solder particles were formed

### Examples 50 to 60

Solder particles were produced, collected and evaluated in the same manner as in Example 49 except that the size of the recess was changed as shown in Table 7. The results are shown in Table 8.

### Example 61

Solder particles were produced, collected and evaluated in the same manner as in Example 1 except that, in Step b1, a base material having a cross-sectional shape shown in (e) of FIG. 2, that is, a plurality of recesses having an opening part of 1.2 μm and an inverted conical shape whose diameter decreased from the opening part to the bottom was used, and the following Step c2 was performed in place of Step c1. The results are shown in Table 8.

### (Step c2) Formation of Solder Particles

The base material in which the solder fine particles were disposed in the recesses in Step b1 was put into a hydrogen radical reduction furnace (plasma reflow device commercially available from Shinko Seiki Co., Ltd.), the furnace was evacuated, hydrogen gas was introduced into the furnace, and the inside of the furnace was filled with hydrogen gas. Then, the temperature of the inside of the furnace was adjusted to 120° C. and hydrogen radicals were emitted for 5 minutes. Then, hydrogen gas in the furnace was removed by evacuation, heating was performed to 170° C., nitrogen was then introduced into the furnace to return to atmospheric pressure, the temperature in the furnace was then lowered to room temperature, and thereby solder particles were formed.

### Examples 62 to 72

Solder particles were produced, collected and evaluated in the same manner as in Example 61 except that the size of the recess was changed as shown in Table 7. The results are shown in Table 8.

### Example 73

Solder particles were produced, collected and evaluated in the same manner as in Example 1 except that, in Step b1, a base material having a cross-sectional shape shown in (h) of FIG. 2, that is, a plurality of recesses having an opening part of 1.2 μm, and a bottom having a continuous curved surface in which the continuous curved surface was convex from the opening part in a depth direction was used, and the following Step c2 was performed in place of Step c1. The results are shown in Table 8. Here, the depth in this case was a distance to a point at which the vertical line drawn from the line parallel to the surface of the base material on which the opening part was positioned intersected the deepest position of the continuous curved surface of the bottom.

### (Step c2) Formation of Solder Particles

The base material in which the solder fine particles were disposed in the recesses in Step b1 was put into a hydrogen radical reduction furnace (plasma reflow device commercially available from Shinko Seiki Co., Ltd.), the furnace was evacuated, hydrogen gas was introduced into the furnace, and the inside of the furnace was filled with hydrogen gas. Then, the temperature in the furnace was adjusted to 120° C. and hydrogen radicals were emitted for 5 minutes. Then, hydrogen gas in the furnace was removed by evacuation, heating was performed to 170° C., nitrogen was then introduced into the furnace to return to atmospheric pressure, the temperature in the furnace was then lowered to room temperature, and thereby solder particles were formed.

### Examples 74 to 84

Solder particles were produced, collected and evaluated in the same manner as in Example 61 except that the size of the recess was changed as shown in Table 7. The results are shown in Table 8.

### Production Examples 13 to 24

An anisotropic conductive film and a connection structure were produced in the same method as in Production Example 1 except that the solder particles produced in the same method as in Examples 49 to 60 were used and a transfer mold having the same shape as the base material used in production of the solder particles of Examples 49 to 60 was used as a transfer mold. The results are shown in Tables 9 to 11.

### Production Examples 25 to 36

An anisotropic conductive film and a connection structure were produced in the same method as in Production Example 1 except that the solder particles produced in the same method as in Examples 61 to 72 were used and a transfer mold having the same shape as the base material used in production of the solder particles of Examples 61 to 72 was used as a transfer mold. The results are shown in Tables 12 to 14.

### Production Examples 37 to 48

An anisotropic conductive film and a connection structure were produced in the same method as in Production Example 1 except that the solder particles produced in the same method as in Examples 73 to 84 were used and a transfer mold having the same shape as the base material used in production of the solder particles of Examples 73 to 84 was used as a transfer mold. The results are shown in Tables 15 to 17.

It was confirmed that the solder particles obtained in Example 49 to Example 60 exhibited the same performance as the solder particles obtained in Example 13 to Example 24. In addition, the solder particles obtained in Example 49 to Example 60 had a shape having a flat portion on a part as in the solder particles obtained in Example 13 to Example 24.

It was confirmed that the solder particles obtained in Example 61 to Example 72 exhibited the same performance as the solder particles obtained in Example 13 to Example 24. In addition, it was confirmed that the solder particles obtained in Example 61 to Example 72 had a pseudo-conical shape in which the cross-sectional diameter continuously changed.

It was confirmed that the solder particles obtained in Example 73 to Example 84 exhibited the same performance as the solder particles obtained in Example 13 to Example 24. In addition, it was confirmed that the solder particles obtained in Example 73 to Example 84 had a pseudo-spherical shape. Here, this shape had an advantage that, when electrodes were connected to each other using a resin adhesive film, the resin was able to be easily removed when a pressure was applied, and the electrodes and the solder particles easily came in contact with each other to obtain a stable connection.

TABLE 7

| | | Example | Example | Example | Example | Example | Example | Example | Example | Example | Example | Example | Example |
|---|---|---|---|---|---|---|---|---|---|---|---|---|---|
| | | 49 | 50 | 51 | 52 | 53 | 54 | 55 | 56 | 57 | 58 | 59 | 60 |
| Opening | μm | 1.2 | 1.7 | 2.3 | 3.3 | 4.3 | 5.3 | 6.3 | 12 | 18 | 30 | 38 | 48 |
| diameter b2 | | | | | | | | | | | | | |
| Opening | μm | 1 | 1.5 | 2 | 3 | 4 | 5 | 6 | 10 | 15 | 25 | 30 | 40 |
| diameter b1 | | | | | | | | | | | | | |
| Bottom | μm | 0.6 | 0.8 | 1.2 | 1.6 | 2 | 2 | 4 | 6 | 7 | 14 | 17 | 25 |
| diameter a | | | | | | | | | | | | | |
| Depth | μm | 1 | 1.5 | 2 | 3 | 4 | 5 | 6 | 10 | 15 | 15 | 15 | 15 |
| Interval | μm | 1 | 1.5 | 2 | 3 | 4 | 5 | 6 | 10 | 15 | 20 | 25 | 30 |
| | | Example | Example | Example | Example | Example | Example | Example | Example | Example | Example | Example | Example |
| | | 61 | 62 | 63 | 64 | 65 | 66 | 67 | 68 | 69 | 70 | 71 | 72 |
| Opening | μm | 1.2 | 1.7 | 2.3 | 3.3 | 4.3 | 5.3 | 6.3 | 12 | 18 | 30 | 38 | 48 |
| diameter b | | | | | | | | | | | | | |
| Depth | μm | 1 | 1.5 | 2 | 3 | 4 | 5 | 6 | 10 | 15 | 15 | 15 | 15 |
| Interval | μm | 1 | 1.5 | 2 | 3 | 4 | 5 | 6 | 10 | 15 | 20 | 25 | 30 |
| | | Example | Example | Example | Example | Example | Example | Example | Example | Example | Example | Example | Example |
| | | 73 | 74 | 75 | 76 | 77 | 78 | 79 | 80 | 81 | 82 | 83 | 84 |
| Opening | μm | 1.2 | 1.7 | 2.3 | 3.3 | 4.3 | 5.3 | 6.3 | 12 | 18 | 30 | 38 | 48 |
| diameter b | | | | | | | | | | | | | |
| Depth | μm | 1 | 1.5 | 2 | 3 | 4 | 5 | 6 | 10 | 15 | 15 | 15 | 15 |
| Interval | μm | 1 | 1.5 | 2 | 3 | 4 | 5 | 6 | 10 | 15 | 20 | 25 | 30 |

TABLE 8

| | | Example | Example | Example | Example | Example | Example | Example | Example | Example | Example | Example | Example |
|---|---|---|---|---|---|---|---|---|---|---|---|---|---|
| | | 49 | 50 | 51 | 52 | 53 | 54 | 55 | 56 | 57 | 58 | 59 | 60 |
| Average | μm | 1.1 | 1.5 | 2 | 3 | 4 | 5 | 6 | 10 | 15 | 20 | 25 | 30 |
| particle | | | | | | | | | | | | | |
| diameter | | | | | | | | | | | | | |
| C.V. value | % | 15 | 15 | 14 | 10 | 7.9 | 7.8 | 6.6 | 5.2 | 4.4 | 4.2 | 3.9 | 3.3 |
| | | Example | Example | Example | Example | Example | Example | Example | Example | Example | Example | Example | Example |
| | | 61 | 62 | 63 | 64 | 65 | 66 | 67 | 68 | 69 | 70 | 71 | 72 |
| Average | μm | 0.9 | 1.3 | 1.8 | 2.7 | 3.8 | 4.8 | 6 | 9 | 14 | 19 | 24 | 29 |
| particle | | | | | | | | | | | | | |
| diameter | | | | | | | | | | | | | |
| C.V. value | % | 19 | 17 | 16 | 13 | 12 | 11 | 9.3 | 8.8 | 7.8 | 6.9 | 6.1 | 5.5 |
| | | Example | Example | Example | Example | Example | Example | Example | Example | Example | Example | Example | Example |
| | | 73 | 74 | 75 | 76 | 77 | 78 | 79 | 80 | 81 | 82 | 83 | 84 |
| Average | μm | 1 | 1.5 | 2 | 3 | 4 | 5 | 6 | 10 | 15 | 20 | 25 | 30 |
| particle | | | | | | | | | | | | | |
| diameter | | | | | | | | | | | | | |
| C.V. value | % | 13 | 13 | 10 | 9.1 | 7.5 | 7.1 | 6.3 | 5 | 4.2 | 4.1 | 3.7 | 3.2 |

TABLE 9

| | | Con- | | | | | | | | | | | | | |
|---|---|---|---|---|---|---|---|---|---|---|---|---|---|---|---|
| | | nec- | | | | | | | | | | | | | |
| | | tion | | Production | Production | Production | Production | Production | Production | Production | Production | Production | Production | Production | Production |
| | | struc- | | Example 13 | Example 14 | Example 15 | Example 16 | Example 17 | Example 18 | Example 19 | Example 20 | Example 21 | Example 22 | Example 23 | Example 24 |
| | | ture | Solder particles | Example 49 | Example 50 | Example 51 | Example 52 | Example 53 | Example 54 | Example 55 | Example 56 | Example 57 | Example 58 | Example 59 | Example 60 |
| Con- | Moisture | (1) | Initial | | | | | | | | | | A | A | A |
| duc- | absorption | | After 100 hours | | | | | | | | | | A | A | A |
| tion | and heat | | After 500 hours | | | | | | | | | | A | A | A |
| resis- | resistance | | After 1,000 hours | | | | | | | | | | A | A | A |
| tance | test | (2) | Initial | | | | | | | | A | A | A | A | |
| | | | After 100 hours | | | | | | | | B | A | A | A | |
| | | | After 500 hours | | | | | | | | B | A | A | A | |
| | | | After 1,000 hours | | | | | | | | B | A | A | A | |
| | | (3) | Initial | | | A | A | A | A | A | A | A | | | |
| | | | After 100 hours | | | B | B | A | A | A | A | A | | | |
| | | | After 500 hours | | | B | B | A | A | A | A | A | | | |
| | | | After 1,000 hours | | | B | B | A | A | A | A | A | | | |
| | | (4) | Initial | | | A | A | A | A | A | A | A | | | |
| | | | After 100 hours | | | B | A | A | A | A | A | A | | | |
| | | | After 500 hours | | | B | A | A | A | A | A | A | | | |
| | | | After 1,000 hours | | | B | A | A | A | A | A | A | | | |
| | | (5) | Initial | A | A | A | A | A | A | A | A | | | | |
| | | | After 100 hours | B | B | A | A | A | A | A | A | | | | |
| | | | After 500 hours | B | B | A | A | A | A | A | A | | | | |
| | | | After 1,000 hours | B | B | A | A | A | A | A | A | | | | |
| | | (6) | Initial | B | A | A | A | A | A | A | | | | | |
| | | | After 100 hours | B | B | A | A | A | A | A | | | | | |
| | | | After 500 hours | B | B | A | A | A | A | A | | | | | |
| | | | After 1,000 hours | B | B | A | A | A | A | A | | | | | |
| | | (7) | Initial | B | A | A | A | A | A | A | | | | | |
| | | | After 100 hours | B | A | A | A | A | A | A | | | | | |
| | | | After 500 hours | B | A | A | A | A | A | A | | | | | |
| | | | After 1,000 hours | B | A | A | A | A | A | A | | | | | |

TABLE 10

| | | Con- | | | | | | | | | | | | | |
|---|---|---|---|---|---|---|---|---|---|---|---|---|---|---|---|
| | | nec- | | | | | | | | | | | | | |
| | | tion | | Production | Production | Production | Production | Production | Production | Production | Production | Production | Production | Production | Production |
| | | struc- | | Example 13 | Example 14 | Example 15 | Example 16 | Example 17 | Example 18 | Example 19 | Example 20 | Example 21 | Example 22 | Example 23 | Example 24 |
| | | ture | Solder particles | Example 49 | Example 50 | Example 51 | Example 52 | Example 53 | Example 54 | Example 55 | Example 56 | Example 57 | Example 58 | Example 59 | Example 60 |
| Con- | High | (1) | Initial | | | | | | | | | | A | A | A |
| duc- | temper- | | After 100 | | | | | | | | | | A | A | A |
| tion | ature | | hours | | | | | | | | | | | | |
| resis- | endur- | | After 500 | | | | | | | | | | A | A | A |
| tance | ance | | hours | | | | | | | | | | | | |
| | test | | After 1,000 | | | | | | | | | | A | A | A |
| | | | hours | | | | | | | | | | | | |
| | | (3) | Initial | | | A | A | A | A | A | A | A | | | |
| | | | After 100 | | | B | A | A | A | A | A | A | | | |
| | | | hours | | | | | | | | | | | | |
| | | | After 500 | | | B | A | A | A | A | A | A | | | |
| | | | hours | | | | | | | | | | | | |
| | | | After 1,000 | | | B | A | A | A | A | A | A | | | |
| | | | hours | | | | | | | | | | | | |
| | | (6) | Initial | A | A | A | A | A | A | A | | | | | |
| | | | After 100 | B | A | A | A | A | A | A | | | | | |
| | | | hours | | | | | | | | | | | | |
| | | | After 500 | B | A | A | A | A | A | A | | | | | |
| | | | hours | | | | | | | | | | | | |
| | | | After 1,000 | B | A | A | A | A | A | A | | | | | |
| | | | hours | | | | | | | | | | | | |

TABLE 11

| | | Con- | | | | | | | | | | | | | |
|---|---|---|---|---|---|---|---|---|---|---|---|---|---|---|---|
| | | nec- | | | | | | | | | | | | | |
| | | tion | | Production | Production | Production | Production | Production | Production | Production | Production | Production | Production | Production | Production |
| | | struc- | | Example 13 | Example 14 | Example 15 | Example 16 | Example 17 | Example 18 | Example 19 | Example 20 | Example 21 | Example 22 | Example 23 | Example 24 |
| | | ture | Solder particles | Example 49 | Example 50 | Example 51 | Example 52 | Example 53 | Example 54 | Example 55 | Example 56 | Example 57 | Example 58 | Example 59 | Example 60 |
| Insu- | Moisture | (1) | Initial | | | | | | | | | | A | A | A |
| lation | absorption | | After 100 hours | | | | | | | | | | A | B | B |
| resis- | and heat | | After 500 hours | | | | | | | | | | A | B | B |
| tance | resistance | | After 1,000 hours | | | | | | | | | | A | B | B |
| | test | (2) | Initial | | | | | | | | A | A | A | A | |
| | | | After 100 hours | | | | | | | | A | A | A | B | |
| | | | After 500 hours | | | | | | | | A | A | A | B | |
| | | | After 1,000 hours | | | | | | | | A | A | A | B | |
| | | (3) | Initial | | | A | A | A | A | A | A | A | | | |
| | | | After 100 hours | | | A | A | A | A | A | A | A | | | |
| | | | After 500 hours | | | A | A | A | A | A | A | A | | | |
| | | | After 1,000 hours | | | A | A | A | A | A | A | A | | | |
| | | (4) | Initial | | | A | A | A | A | A | A | A | | | |
| | | | After 100 hours | | | A | A | A | A | A | A | B | | | |
| | | | After 500 hours | | | A | A | A | A | A | A | B | | | |
| | | | After 1,000 hours | | | A | A | A | A | A | A | B | | | |
| | | (5) | Initial | A | A | A | A | A | A | A | A | | | | |
| | | | After 100 hours | A | A | A | A | A | A | A | B | | | | |
| | | | After 500 hours | A | A | A | A | A | A | A | B | | | | |
| | | | After 1,000 hours | A | A | A | A | A | A | A | B | | | | |
| | | (6) | Initial | A | A | A | A | A | A | A | | | | | |
| | | | After 100 hours | A | A | A | A | A | B | | | | | | |
| | | | After 500 hours | A | A | A | A | A | B | | | | | | |
| | | | After 1,000 hours | A | A | A | A | A | B | | | | | | |
| | | (7) | Initial | A | A | A | A | | | | | | | | |
| | | | After 100 hours | A | A | A | B | | | | | | | | |
| | | | After 500 hours | A | A | A | B | | | | | | | | |
| | | | After 1,000 hours | A | A | A | B | | | | | | | | |

TABLE 12

| | | Con- | | | | | | | | | | | | | |
|---|---|---|---|---|---|---|---|---|---|---|---|---|---|---|---|
| | | nec- | | | | | | | | | | | | | |
| | | tion | | Production | Production | Production | Production | Production | Production | Production | Production | Production | Production | Production | Production |
| | | struc- | | Example 25 | Example 26 | Example 27 | Example 28 | Example 29 | Example 30 | Example 31 | Example 32 | Example 33 | Example 34 | Example 35 | Example 36 |
| | | ture | Solder particles | Example 61 | Example 62 | Example 63 | Example 64 | Example 65 | Example 66 | Example 67 | Example 68 | Example 69 | Example 70 | Example 71 | Example 72 |
| Con- | Moisture | (1) | Initial | | | | | | | | | | A | A | A |
| duc- | absorption | | After 100 hours | | | | | | | | | | A | A | A |
| tion | and heat | | After 500 hours | | | | | | | | | | A | A | A |
| resis- | resistance | | After 1,000 hours | | | | | | | | | | A | A | A |
| tance | test | (2) | Initial | | | | | | | | A | A | A | A | |
| | | | After 100 hours | | | | | | | | B | A | A | A | |
| | | | After 500 hours | | | | | | | | B | A | A | A | |
| | | | After 1,000 hours | | | | | | | | B | A | A | A | |
| | | (3) | Initial | | | A | A | A | A | A | A | A | | | |
| | | | After 100 hours | | | B | B | A | A | A | A | A | | | |
| | | | After 500 hours | | | B | B | A | A | A | A | A | | | |
| | | | After 1,000 hours | | | B | B | A | A | A | A | A | | | |
| | | (4) | Initial | | | A | A | A | A | A | A | A | | | |
| | | | After 100 hours | | | B | A | A | A | A | A | A | | | |
| | | | After 500 hours | | | B | A | A | A | A | A | A | | | |
| | | | After 1,000 hours | | | B | A | A | A | A | A | A | | | |
| | | (5) | Initial | A | A | A | A | A | A | A | A | | | | |
| | | | After 100 hours | B | B | A | A | A | A | A | A | | | | |
| | | | After 500 hours | B | B | A | A | A | A | A | A | | | | |
| | | | After 1,000 hours | B | B | A | A | A | A | A | A | | | | |
| | | (6) | Initial | B | A | A | A | A | A | A | | | | | |
| | | | After 100 hours | B | B | A | A | A | A | A | | | | | |
| | | | After 500 hours | B | B | A | A | A | A | A | | | | | |
| | | | After 1,000 hours | B | B | A | A | A | A | A | | | | | |
| | | (7) | Initial | B | A | A | A | A | A | A | | | | | |
| | | | After 100 hours | B | A | A | A | A | A | A | | | | | |
| | | | After 500 hours | B | A | A | A | A | A | A | | | | | |
| | | | After 1,000 hours | B | A | A | A | A | A | A | | | | | |

TABLE 13

| | | Con- | | | | | | | | | | | | | |
|---|---|---|---|---|---|---|---|---|---|---|---|---|---|---|---|
| | | nec- | | | | | | | | | | | | | |
| | | tion | | Production | Production | Production | Production | Production | Production | Production | Production | Production | Production | Production | Production |
| | | struc- | | Example 25 | Example 26 | Example 27 | Example 28 | Example 29 | Example 30 | Example 31 | Example 32 | Example 33 | Example 34 | Example 35 | Example 36 |
| | | ture | Solder particles | Example 61 | Example 62 | Example 63 | Example 64 | Example 65 | Example 66 | Example 67 | Example 68 | Example 69 | Example 70 | Example 71 | Example 72 |
| Con- | High | (1) | Initial | | | | | | | | | | A | A | A |
| duc- | temper- | | After 100 | | | | | | | | | | A | A | A |
| tion | ature | | hours | | | | | | | | | | | | |
| resis- | endur- | | After 500 | | | | | | | | | | A | A | A |
| tance | ance | | hours | | | | | | | | | | | | |
| | test | | After 1,000 | | | | | | | | | | A | A | A |
| | | | hours | | | | | | | | | | | | |
| | | (3) | Initial | | | A | A | A | A | A | A | A | | | |
| | | | After 100 | | | B | A | A | A | A | A | A | | | |
| | | | hours | | | | | | | | | | | | |
| | | | After 500 | | | B | A | A | A | A | A | A | | | |
| | | | hours | | | | | | | | | | | | |
| | | | After 1,000 | | | B | B | A | A | A | A | A | | | |
| | | | hours | | | | | | | | | | | | |
| | | (6) | Initial | B | A | A | A | A | A | A | | | | | |
| | | | After 100 | B | A | A | A | A | A | A | | | | | |
| | | | hours | | | | | | | | | | | | |
| | | | After 500 | B | B | B | A | A | A | A | | | | | |
| | | | hours | | | | | | | | | | | | |
| | | | After 1,000 | B | B | B | B | A | A | A | | | | | |
| | | | hours | | | | | | | | | | | | |

TABLE 14

| | | Con- | | | | | | | | | | | | | |
|---|---|---|---|---|---|---|---|---|---|---|---|---|---|---|---|
| | | nec- | | | | | | | | | | | | | |
| | | tion | | Production | Production | Production | Production | Production | Production | Production | Production | Production | Production | Production | Production |
| | | struc- | | Example 25 | Example 26 | Example 27 | Example 28 | Example 29 | Example 30 | Example 31 | Example 32 | Example 33 | Example 34 | Example 35 | Example 36 |
| | | ture | Solder particles | Example 61 | Example 62 | Example 63 | Example 64 | Example 65 | Example 66 | Example 67 | Example 68 | Example 69 | Example 70 | Example 71 | Example 72 |
| Insu- | Moisture | (1) | Initial | | | | | | | | | | A | A | A |
| lation | absorption | | After 100 hours | | | | | | | | | | A | B | B |
| resis- | and heat | | After 500 hours | | | | | | | | | | A | B | B |
| tance | resistance | | After 1,000 hours | | | | | | | | | | A | B | B |
| | test | (2) | Initial | | | | | | | | A | A | A | A | |
| | | | After 100 hours | | | | | | | | A | A | A | B | |
| | | | After 500 hours | | | | | | | | A | A | A | B | |
| | | | After 1,000 hours | | | | | | | | A | A | A | B | |
| | | (3) | Initial | | | A | A | A | A | A | A | A | | | |
| | | | After 100 hours | | | A | A | A | A | A | A | A | | | |
| | | | After 500 hours | | | A | A | A | A | A | A | A | | | |
| | | | After 1,000 hours | | | A | A | A | A | A | A | A | | | |
| | | (4) | Initial | | | A | A | A | A | A | A | A | | | |
| | | | After 100 hours | | | A | A | A | A | A | A | B | | | |
| | | | After 500 hours | | | A | A | A | A | A | A | B | | | |
| | | | After 1,000 hours | | | A | A | A | A | A | A | B | | | |
| | | (5) | Initial | A | A | A | A | A | A | A | A | | | | |
| | | | After 100 hours | A | A | A | A | A | A | A | B | | | | |
| | | | After 500 hours | A | A | A | A | A | A | A | B | | | | |
| | | | After 1,000 hours | A | A | A | A | A | A | A | B | | | | |
| | | (6) | Initial | A | A | A | A | A | A | A | | | | | |
| | | | After 100 hours | A | A | A | A | A | B | | | | | | |
| | | | After 500 hours | A | A | A | A | A | B | | | | | | |
| | | | After 1,000 hours | A | A | A | A | A | B | | | | | | |
| | | (7) | Initial | A | A | A | A | | | | | | | | |
| | | | After 100 hours | A | A | A | B | | | | | | | | |
| | | | After 500 hours | A | A | A | B | | | | | | | | |
| | | | After 1,000 hours | A | A | A | B | | | | | | | | |

TABLE 15

| | | Con- | | | | | | | | | | | | | |
|---|---|---|---|---|---|---|---|---|---|---|---|---|---|---|---|
| | | nec- | | | | | | | | | | | | | |
| | | tion | | Production | Production | Production | Production | Production | Production | Production | Production | Production | Production | Production | Production |
| | | struc- | | Example 37 | Example 38 | Example 39 | Example 40 | Example 41 | Example 42 | Example 43 | Example 44 | Example 45 | Example 46 | Example 47 | Example 48 |
| | | ture | Solder particles | Example 73 | Example 74 | Example 75 | Example 76 | Example 77 | Example 78 | Example 79 | Example 80 | Example 81 | Example 82 | Example 83 | Example 84 |
| Con- | Moisture | (1) | Initial | | | | | | | | | | A | A | A |
| duc- | absorption | | After 100 hours | | | | | | | | | | A | A | A |
| tion | and heat | | After 500 hours | | | | | | | | | | A | A | A |
| resis- | resistance | | After 1,000 hours | | | | | | | | | | A | A | A |
| tance | test | (2) | Initial | | | | | | | | A | A | A | A | |
| | | | After 100 hours | | | | | | | | B | A | A | A | |
| | | | After 500 hours | | | | | | | | B | A | A | A | |
| | | | After 1,000 hours | | | | | | | | B | A | A | A | |
| | | (3) | Initial | | | A | A | A | A | A | A | A | | | |
| | | | After 100 hours | | | A | A | A | A | A | A | A | | | |
| | | | After 500 hours | | | B | A | A | A | A | A | A | | | |
| | | | After 1,000 hours | | | B | A | A | A | A | A | A | | | |
| | | (4) | Initial | | | A | A | A | A | A | A | A | | | |
| | | | After 100 hours | | | A | A | A | A | A | A | A | | | |
| | | | After 500 hours | | | A | A | A | A | A | A | A | | | |
| | | | After 1,000 hours | | | B | A | A | A | A | A | A | | | |
| | | (5) | Initial | A | A | A | A | A | A | A | A | | | | |
| | | | After 100 hours | A | A | A | A | A | A | A | A | | | | |
| | | | After 500 hours | B | B | A | A | A | A | A | A | | | | |
| | | | After 1,000 hours | B | B | A | A | A | A | A | A | | | | |
| | | (6) | Initial | A | A | A | A | A | A | A | | | | | |
| | | | After 100 hours | A | A | A | A | A | A | A | | | | | |
| | | | After 500 hours | B | B | A | A | A | A | A | | | | | |
| | | | After 1,000 hours | B | B | A | A | A | A | A | | | | | |
| | | (7) | Initial | B | A | A | A | A | A | A | | | | | |
| | | | After 100 hours | B | A | A | A | A | A | A | | | | | |
| | | | After 500 hours | B | A | A | A | A | A | A | | | | | |
| | | | After 1,000 hours | B | A | A | A | A | A | A | | | | | |

TABLE 16

| | | Con- | | | | | | | | | | | | | |
|---|---|---|---|---|---|---|---|---|---|---|---|---|---|---|---|
| | | nec- | | | | | | | | | | | | | |
| | | tion | | Production | Production | Production | Production | Production | Production | Production | Production | Production | Production | Production | Production |
| | | struc- | | Example 37 | Example 38 | Example 39 | Example 40 | Example 41 | Example 42 | Example 43 | Example 44 | Example 45 | Example 46 | Example 47 | Example 48 |
| | | ture | Solder particles | Example 73 | Example 74 | Example 75 | Example 76 | Example 77 | Example 78 | Example 79 | Example 80 | Example 81 | Example 82 | Example 83 | Example 84 |
| Con- | High | (1) | Initial | | | | | | | | | | A | A | A |
| duc- | temper- | | After 100 | | | | | | | | | | A | A | A |
| tion | ature | | hours | | | | | | | | | | | | |
| resis- | endur- | | After 500 | | | | | | | | | | A | A | A |
| tance | ance | | hours | | | | | | | | | | | | |
| | test | | After 1,000 | | | | | | | | | | A | A | A |
| | | | hours | | | | | | | | | | | | |
| | | (3) | Initial | | | A | A | A | A | A | A | A | | | |
| | | | After 100 | | | A | A | A | A | A | A | A | | | |
| | | | hours | | | | | | | | | | | | |
| | | | After 500 | | | A | A | A | A | A | A | A | | | |
| | | | hours | | | | | | | | | | | | |
| | | | After 1,000 | | | B | A | A | A | A | A | A | | | |
| | | | hours | | | | | | | | | | | | |
| | | (6) | Initial | A | A | A | A | A | A | A | | | | | |
| | | | After 100 | A | A | A | A | A | A | A | | | | | |
| | | | hours | | | | | | | | | | | | |
| | | | After 500 | B | A | A | A | A | A | A | | | | | |
| | | | hours | | | | | | | | | | | | |
| | | | After 1,000 | B | A | A | A | A | A | A | | | | | |
| | | | hours | | | | | | | | | | | | |

TABLE 17

| | | Con- | | | | | | | | | | | | | |
|---|---|---|---|---|---|---|---|---|---|---|---|---|---|---|---|
| | | nec- | | | | | | | | | | | | | |
| | | tion | | Production | Production | Production | Production | Production | Production | Production | Production | Production | Production | Production | Production |
| | | struc- | | Example 37 | Example 38 | Example 39 | Example 40 | Example 41 | Example 42 | Example 43 | Example 44 | Example 45 | Example 46 | Example 47 | Example 48 |
| | | ture | Solder particles | Example 73 | Example 74 | Example 75 | Example 76 | Example 77 | Example 78 | Example 79 | Example 80 | Example 81 | Example 82 | Example 83 | Example 84 |
| Insu- | Moisture | (1) | Initial | | | | | | | | | | A | A | A |
| lation | absorption | | After 100 hours | | | | | | | | | | A | A | A |
| resis- | and heat | | After 500 hours | | | | | | | | | | A | B | B |
| tance | resistance | | After 1,000 hours | | | | | | | | | | A | B | B |
| | test | (2) | Initial | | | | | | | | A | A | A | A | |
| | | | After 100 hours | | | | | | | | A | A | A | B | |
| | | | After 500 hours | | | | | | | | A | A | A | B | |
| | | | After 1,000 hours | | | | | | | | A | A | A | B | |
| | | (3) | Initial | | | A | A | A | A | A | A | A | | | |
| | | | After 100 hours | | | A | A | A | A | A | A | A | | | |
| | | | After 500 hours | | | A | A | A | A | A | A | A | | | |
| | | | After 1,000 hours | | | A | A | A | A | A | A | A | | | |
| | | (4) | Initial | | | A | A | A | A | A | A | A | | | |
| | | | After 100 hours | | | A | A | A | A | A | A | B | | | |
| | | | After 500 hours | | | A | A | A | A | A | A | B | | | |
| | | | After 1,000 hours | | | A | A | A | A | A | A | B | | | |
| | | (5) | Initial | A | A | A | A | A | A | A | A | | | | |
| | | | After 100 hours | A | A | A | A | A | A | A | B | | | | |
| | | | After 500 hours | A | A | A | A | A | A | A | B | | | | |
| | | | After 1,000 hours | A | A | A | A | A | A | A | B | | | | |
| | | (6) | Initial | A | A | A | A | A | A | A | | | | | |
| | | | After 100 hours | A | A | A | A | A | B | | | | | | |
| | | | After 500 hours | A | A | A | A | A | B | | | | | | |
| | | | After 1,000 hours | A | A | A | A | A | B | | | | | | |
| | | (7) | Initial | A | A | A | A | | | | | | | | |
| | | | After 100 hours | A | A | A | B | | | | | | | | |
| | | | After 500 hours | A | A | A | B | | | | | | | | |
| | | | After 1,000 hours | A | A | A | B | | | | | | | | |

### Examples 85 to 87

Solder particles were produced, collected and evaluated in the same manner as in Example 1 except that, in Step a1, 10 g of Sn—Bi solder fine particles (Type 9 commercially available from 5N Plus, a melting point of 139° C., an average particle diameter of 3.0 μm, and a C.V. value of 32%) were used, the recess shown in Table 18 was used in Step b1, and the following Step c2 was performed in place of Step c1. The results are shown in Table 19.

### (Step c2) Formation of Solder Particles

The base material in which the solder fine particles were disposed in the recesses in Step b1 was put into a hydrogen radical reduction furnace (plasma reflow device commercially available from Shinko Seiki Co., Ltd.), the furnace was evacuated, hydrogen gas was introduced into the furnace, and the inside of the furnace was filled with hydrogen gas. Then, the temperature in the furnace was adjusted to 120° C. and hydrogen radicals were emitted for 5 minutes. Then, hydrogen gas in the furnace was removed by evacuation, heating was performed to 170° C., nitrogen was then introduced into the furnace to return to atmospheric pressure, the temperature in the furnace was then lowered to room temperature, and thereby solder particles were formed.

### Examples 88 to 90

Solder particles were produced, collected and evaluated in the same manner as in Example 1 except that, in Step a1, 10 g of Sn—Bi solder fine particles (Type 10 commercially available from 5N Plus, a melting point of 139° C., an average particle diameter: 2.8 μm, and a C.V. value of 28%) were used, the recess shown in Table 18 was used in Step b1, and the following Step c2 was performed in place of Step c1. The results are shown in Table 19.

### (Step c2) Formation of Solder Particles

The base material in which the solder fine particles were disposed in the recesses in Step b1 was put into a hydrogen radical reduction furnace (plasma reflow device commercially available from Shinko Seiki Co., Ltd.), the furnace was evacuated, hydrogen gas was introduced into the furnace, and the inside of the furnace was filled with hydrogen gas. Then, the temperature in the furnace was adjusted to 120° C. and hydrogen radicals were emitted for 5 minutes. Then, hydrogen gas in the furnace was removed by evacuation, heating was performed to 170° C., nitrogen was then introduced into the furnace to return to atmospheric pressure, the temperature in the furnace was then lowered to room temperature, and thereby solder particles were formed.

### Examples 91 to 93

100 g of In—Sn solder fine particles (Type 8 commercially available from 5N Plus, a melting point of 120° C.) were immersed in distilled water and ultrasonically dispersed and then left, the solder fine particles suspended in the supernatant were collected, and solder fine particles having an average particle diameter of 1.0 μm and a C.V. value of 40% were obtained. Solder particles were produced, collected and evaluated in the same manner as in Example 1 except that the solder fine particles (an average particle diameter of 1.0 μm and a C.V. value of 40%) were used in Step a1, the recess shown in Table 18 was used in Step b1, and the following Step c2 was performed in place of Step c1. The results are shown in Table 19.

### (Step c2) Formation of Solder Particles

The base material in which the solder fine particles were disposed in the recesses in Step b1 was put into a hydrogen radical reduction furnace (plasma reflow device commercially available from Shinko Seiki Co., Ltd.), the furnace was evacuated, hydrogen gas was then introduced into the furnace, and the inside of the furnace was filled with hydrogen gas. Then, the temperature in the furnace was adjusted to 110° C. and hydrogen radicals were emitted for 5 minutes. Then, hydrogen gas in the furnace was removed by evacuation, heating was performed to 160° C., nitrogen was then introduced into the furnace to return to atmospheric pressure, the temperature in the furnace was then lowered to room temperature, and thereby solder particles were formed.

### Examples 94 to 96

100 g of Sn—Ag—Cu solder fine particles (Type 8 commercially available from 5N Plus, a melting point of 218° C.) were immersed in distilled water and ultrasonically dispersed and then left, the solder fine particles suspended in the supernatant were collected, and solder fine particles having an average particle diameter of 1.0 μm and a C.V. value of 41% were obtained. Solder particles were produced, collected and evaluated in the same manner as in Example 1 except that the solder fine particles (an average particle diameter of 1.0 μm and a C.V. value of 41%) were used in Step a1, the recess shown in Table 18 was used in Step b1, and the following Step c2 was performed in place of Step c1. The results are shown in Table 19.

### (Step c2) Formation of Solder Particles

The base material in which the solder fine particles were disposed in the recesses in Step b1 was put into a hydrogen radical reduction furnace (plasma reflow device commercially available from Shinko Seiki Co., Ltd.), the furnace was evacuated, hydrogen gas was then introduced into the furnace, and the inside of the furnace was filled with hydrogen gas. Then, the temperature in the furnace was adjusted to 150° C. and hydrogen radicals were emitted for 3 minutes. Then, hydrogen gas in the furnace was removed by evacuation, heating was performed to 240° C., nitrogen was then introduced into the furnace to return to atmospheric pressure, the temperature in the furnace was then lowered to room temperature, and thereby solder particles were formed.

### Production Examples 49 to 51

An anisotropic conductive film and a connection structure were produced in the same method as in Production Example 1 except that the solder particles produced in the same method as in Examples 85 to 87 were used and a transfer mold having the same shape as the base material used in production of the solder particles of Examples 85 to 87 was used as a transfer mold. The results are shown in Tables 20 to 22.

### Production Examples 52 to 54

An anisotropic conductive film and a connection structure were produced in the same method as in Production Example 1 except that the solder particles produced in the same method as in Examples 88 to 90 were used and a transfer mold having the same shape as the base material used in production of the solder particles of Examples 88 to 90 was used as a transfer mold. The results are shown in Tables 20 to 22.

### Production Examples 55 to 57

An anisotropic conductive film and a connection structure were produced in the same method as in Production Example 1 except that the solder particles produced in the same method as in Examples 91 to 93 were used and a transfer mold having the same shape as the base material used in production of the solder particles of Examples 91 to 93 was used as a transfer mold. The results are shown in Tables 20 to 22.

### Production Examples 58 to 60

An anisotropic conductive film and a connection structure were produced in the same method as in Production Example 1 except that the solder particles produced in the same method as in Examples 94 to 96 were used, a transfer mold having the same shape as the base material used in production of the solder particles of Examples 94 to 96 was used as a transfer mold, and in Step 11, the main compression temperature was set to 230° C. The results are shown in Tables 20 to 22.

TABLE 18

| | | Example | Example | Example | Example | Example | Example | Example | Example | Example | Example | Example | Example |
|---|---|---|---|---|---|---|---|---|---|---|---|---|---|
| | | 85 | 86 | 87 | 88 | 89 | 90 | 91 | 92 | 93 | 94 | 95 | 96 |
| Opening | μm | 4.3 | 11 | 40 | 4.3 | 11 | 40 | 4.3 | 11 | 40 | 4.3 | 11 | 40 |
| diameter | | | | | | | | | | | | | |
| Bottom | μm | 4 | 10 | 40 | 4 | 10 | 40 | 4 | 10 | 40 | 4 | 10 | 40 |
| diameter | | | | | | | | | | | | | |
| Depth | μm | 4 | 10 | 15 | 4 | 10 | 15 | 4 | 10 | 15 | 4 | 10 | 15 |
| Interval | μm | 4 | 10 | 30 | 4 | 10 | 30 | 4 | 10 | 30 | 4 | 10 | 30 |

TABLE 19

| | | Example | Example | Example | Example | Example | Example | Example | Example | Example | Example | Example | Example |
|---|---|---|---|---|---|---|---|---|---|---|---|---|---|
| | | 85 | 86 | 87 | 88 | 89 | 90 | 91 | 92 | 93 | 94 | 95 | 96 |
| Average | μm | 4 | 10 | 30 | 4 | 10 | 30 | 4 | 10 | 30 | 4 | 10 | 30 |
| particle | | | | | | | | | | | | | |
| diameter | | | | | | | | | | | | | |
| C.V. value | % | 7.4 | 5 | 3.1 | 6.7 | 4.9 | 3 | 8.3 | 5.2 | 3.2 | 7.5 | 5.2 | 5.2 |

TABLE 20

| | | Con- | | | | | | | | | | | | | |
|---|---|---|---|---|---|---|---|---|---|---|---|---|---|---|---|
| | | nec- | | | | | | | | | | | | | |
| | | tion | | Production | Production | Production | Production | Production | Production | Production | Production | Production | Production | Production | Production |
| | | struc- | | Example 49 | Example 50 | Example 51 | Example 52 | Example 53 | Example 54 | Example 55 | Example 56 | Example 57 | Example 58 | Example 59 | Example 60 |
| | | ture | Solder particles | Example 85 | Example 86 | Example 87 | Example 88 | Example 89 | Example 90 | Example 91 | Example 92 | Example 93 | Example 94 | Example 95 | Example 96 |
| Con- | Moisture | (1) | Initial | | | A | | | A | | | A | | | A |
| duc- | absorption | | After 100 hours | | | A | | | A | | | A | | | A |
| tion | and heat | | After 500 hours | | | A | | | A | | | A | | | A |
| resis- | resistance | | After 1,000 hours | | | A | | | A | | | A | | | A |
| tance | test | (2) | Initial | | A | | | A | | | A | | | A | |
| | | | After 100 hours | | B | | | B | | | B | | | B | |
| | | | After 500 hours | | B | | | B | | | B | | | B | |
| | | | After 1,000 hours | | B | | | B | | | B | | | B | |
| | | (3) | Initial | A | A | | A | A | | A | A | | A | A | |
| | | | After 100 hours | A | A | | A | A | | A | A | | A | A | |
| | | | After 500 hours | A | A | | A | A | | A | A | | A | A | |
| | | | After 1,000 hours | A | A | | A | A | | A | A | | A | A | |
| | | (4) | Initial | A | A | | A | A | | A | A | | A | A | |
| | | | After 100 hours | A | A | | A | A | | A | A | | A | A | |
| | | | After 500 hours | A | A | | A | A | | A | A | | A | A | |
| | | | After 1,000 hours | A | A | | A | A | | A | A | | A | A | |
| | | (5) | Initial | A | A | | A | A | | A | A | | A | A | |
| | | | After 100 hours | A | A | | A | A | | A | A | | A | A | |
| | | | After 500 hours | A | A | | A | A | | A | A | | A | A | |
| | | | After 1,000 hours | A | A | | A | A | | A | A | | A | A | |
| | | (6) | Initial | A | | | A | | | A | | | A | | |
| | | | After 100 hours | A | | | A | | | A | | | A | | |
| | | | After 500 hours | A | | | A | | | A | | | A | | |
| | | | After 1,000 hours | A | | | A | | | A | | | A | | |
| | | (7) | Initial | A | | | A | | | A | | | A | | |
| | | | After 100 hours | | | | | A | A | A | | | | | |
| | | | After 500 hours | B | A | A | A | A | A | A | | | | | |
| | | | After 1,000 hours | B | A | A | A | A | A | A | | | | | |

TABLE 21

| | | Con- | | | | | | | | | | | | | |
|---|---|---|---|---|---|---|---|---|---|---|---|---|---|---|---|
| | | nec- | | | | | | | | | | | | | |
| | | tion | | Production | Production | Production | Production | Production | Production | Production | Production | Production | Production | Production | Production |
| | | struc- | | Example 49 | Example 50 | Example 51 | Example 52 | Example 53 | Example 54 | Example 55 | Example 56 | Example 57 | Example 58 | Example 59 | Example 60 |
| | | ture | Solder particles | Example 85 | Example 86 | Example 87 | Example 88 | Example 89 | Example 90 | Example 91 | Example 92 | Example 93 | Example 94 | Example 95 | Example 96 |
| Con- | High | (1) | Initial | | | A | | | A | | | A | | | A |
| duc- | temper- | | After 100 | | | A | | | A | | | A | | | A |
| tion | ature | | hours | | | | | | | | | | | | |
| resis- | endur- | | After 500 | | | A | | | A | | | A | | | A |
| tance | ance | | hours | | | | | | | | | | | | |
| | test | | After 1,000 | | | A | | | A | | | A | | | A |
| | | | hours | | | | | | | | | | | | |
| | | (3) | Initial | A | A | | A | A | | A | A | | A | A | |
| | | | After 100 | A | A | | A | A | | A | A | | A | A | |
| | | | hours | | | | | | | | | | | | |
| | | | After 500 | A | A | | A | A | | A | A | | A | A | |
| | | | hours | | | | | | | | | | | | |
| | | | After 1,000 | A | A | | A | A | | A | A | | A | A | |
| | | | hours | | | | | | | | | | | | |
| | | (6) | Initial | A | | | A | | | A | | | A | | |
| | | | After 100 | A | | | A | | | A | | | A | | |
| | | | hours | | | | | | | | | | | | |
| | | | After 500 | A | | | A | | | A | | | A | | |
| | | | hours | | | | | | | | | | | | |
| | | | After 1,000 | A | | | A | | | A | | | A | | |
| | | | hours | | | | | | | | | | | | |

TABLE 22

| | | Con- | | | | | | | | | | | | | |
|---|---|---|---|---|---|---|---|---|---|---|---|---|---|---|---|
| | | nec- | | | | | | | | | | | | | |
| | | tion | | Production | Production | Production | Production | Production | Production | Production | Production | Production | Production | Production | Production |
| | | struc- | | Example 49 | Example 50 | Example 51 | Example 52 | Example 53 | Example 54 | Example 55 | Example 56 | Example 57 | Example 58 | Example 59 | Example 60 |
| | | ture | Solder particles | Example 85 | Example 86 | Example 87 | Example 88 | Example 89 | Example 90 | Example 91 | Example 92 | Example 93 | Example 94 | Example 95 | Example 96 |
| Insu- | Moisture | (1) | Initial | | | A | | | A | | | A | | | A |
| lation | absorption | | After 100 hours | | | B | | | B | | | B | | | B |
| resis- | and heat | | After 500 hours | | | B | | | B | | | B | | | B |
| tance | resistance | | After 1,000 hours | | | B | | | B | | | B | | | B |
| | test | (2) | Initial | | A | | | A | | | A | | | A | |
| | | | After 100 hours | | A | | | A | | | A | | | A | |
| | | | After 500 hours | | A | | | A | | | A | | | A | |
| | | | After 1,000 hours | | A | | | A | | | A | | | A | |
| | | (3) | Initial | A | A | | A | A | | A | A | | A | A | |
| | | | After 100 hours | A | A | | A | A | | A | A | | A | A | |
| | | | After 500 hours | A | A | | A | A | | A | A | | A | A | |
| | | | After 1,000 hours | A | A | | A | A | | A | A | | A | A | |
| | | (4 ) | Initial | A | A | | A | A | | A | A | | A | A | |
| | | | After 100 hours | A | A | | A | A | | A | A | | A | A | |
| | | | After 500 hours | A | A | | A | A | | A | A | | A | A | |
| | | | After 1,000 hours | A | A | | A | A | | A | A | | A | A | |
| | | (5) | Initial | A | A | | A | A | | A | A | | A | A | |
| | | | After 100 hours | A | B | | A | B | | A | B | | A | B | |
| | | | After 500 hours | A | B | | A | B | | A | B | | A | B | |
| | | | After 1,000 hours | A | B | | A | B | | A | B | | A | B | |
| | | (6) | Initial | A | | | A | | | A | | | A | | |
| | | | After 100 hours | A | | | A | | | A | | | A | | |
| | | | After 500 hours | A | | | A | | | A | | | A | | |
| | | | After 1,000 hours | A | | | A | | | A | | | A | | |

When the size of the recess was small (for example, a bottom of 2 to 3 μm), the C.V value of the obtained solder particles tended to be lower as the central particle diameter of the solder fine particles was smaller. This is thought to be caused by the fact that, as the central particle diameter of the solder fine particles was smaller, the filling rate in the recess was higher, and the filling variation among the plurality of recesses was lower.

Based on the above examples, according to the method of the present invention, it was confirmed that solder particles having a uniform particle diameter and different melting points were easily obtained by simply changing the composition of the solder fine particles.

In addition, various cross-sectional shapes of the recesses could be used. That is, the cross-sectional shape of the recess could be appropriately selected according to the final usage method and form of the solder particles. For example, in the case of the solder particles were dispersed in the resin and flowability was secured like an ink, it is considered preferable for the surface of the solder particles to have a continuous curved surface. On the other hand, in the case of the solder particles were dispersed in the film and the solder particles were brought into contact with electrodes in a compression step, when the solder particles had a flat portion, an impact during contact could be alleviated and damage to the electrode could be prevented. In addition, the resin whose viscosity was lowered due to heating in the compression step flowed and moved on the electrode. However, when the particles had a flat portion, since an area in contact with the electrode tended to be large and the particles quickly wet and spread on the electrode when the oxide film was removed by the flux, there was also an advantage of movement due to the resin flow being restricted. The same phenomenon was observed in the resin paste. When the cross-sectional shape of the recess was conical toward the bottom as shown in (e) of FIG. 2, the obtained solder particles had no acute angle part due to surface tension of the solder but had a pseudo-conical shape whose cross-sectional diameter continuously changed. For example, since such particles could be aligned and disposed in the thickness direction of the resin film, there were advantages that, during compression and mounting, a pseudo-conical part with a narrower cross section improved a resin exclusion property, the solder particles easily came in contact with the electrodes, and a stable connection was obtained.

### REFERENCE SIGNS LIST

1 Solder particles
11 Flat portion
111 Solder fine particles
60 Base material
60a Surface
62 Recess
62a Bottom

1. A method for producing solder particles, comprising:
a preparation step in which a base material having a plurality of recesses and solder fine particles are prepared;
an accommodation step in which at least some of the solder fine particles are accommodated in the recesses; and
a fusing step in which the solder fine particles accommodated in the recesses are fused and the solder particles are formed inside the recesses,
wherein the solder particles have an average particle diameter of 1 μm to 30 μm and the solder particles have an C.V. value of 20% or less.

2. The method for producing solder particles according to claim 1,
wherein the C.V. value of the solder fine particles prepared in the preparation step is more than 20%.

3. The method for producing solder particles according to claim 1,
wherein, before the fusing step, the solder fine particles accommodated in the recesses are exposed to a reducing atmosphere.

4. The method for producing solder particles according to claim 1,
wherein, in the fusing step, the solder fine particles accommodated in the recesses are fused under a reducing atmosphere.

5. The method for producing solder particles according to claim 1,
wherein the solder fine particles prepared in the preparation step include at least one selected from a group consisting of tin, tin alloys, indium and indium alloys.

6. The method for producing solder particles according to claim 5,
wherein the solder fine particles prepared in the preparation step include at least one selected from a group consisting of In—Bi alloys, In—Sn alloys, In—Sn—Ag alloys, Sn—Au alloys, Sn—Bi alloys, Sn—Bi—Ag alloys, Sn—Ag—Cu alloys and Sn—Cu alloys.

7. A solder particle having an average particle diameter of 1 μm to 30 μm and a C.V. value of 20% or less.

8. The solder particle according to claim 7,
wherein a quadrangle circumscribing a projected image of the solder particle is created by two pairs of parallel lines, and distances between opposite sides are set as X and Y, where Y<X, X and Y satisfy the following formula:
0.8<Y/X<1.0.

9. The solder particle according to claim 7,
comprising at least one selected from a group consisting of tin, tin alloys, indium and indium alloys.

10. The solder particle according to claim 7, comprising at least one selected from a group consisting of In—Bi alloys, In—Sn alloys, In—Sn—Ag alloys, Sn—Au alloys, Sn—Bi alloys, Sn—Bi—Ag alloys, Sn—Ag—Cu alloys and Sn—Cu alloys.

11. The method for producing solder particles according to claim 2,
wherein, before the fusing step, the solder fine particles accommodated in the recesses are exposed to a reducing atmosphere.

12. The method for producing solder particles according to claim 2,
wherein, in the fusing step, the solder fine particles accommodated in the recesses are fused under a reducing atmosphere.

13. The method for producing solder particles according to claim 3,
wherein, in the fusing step, the solder fine particles accommodated in the recesses are fused under a reducing atmosphere.

14. The method for producing solder particles according to claim 2,
wherein the solder fine particles prepared in the preparation step include at least one selected from a group consisting of tin, tin alloys, indium and indium alloys.

15. The method for producing solder particles according to claim 3,
wherein the solder fine particles prepared in the preparation step include at least one selected from a group consisting of tin, tin alloys, indium and indium alloys.

16. The method for producing solder particles according to claim 4,
wherein the solder fine particles prepared in the preparation step include at least one selected from a group consisting of tin, tin alloys, indium and indium alloys.

17. The method for producing solder particles according to claim 14,
wherein the solder fine particles prepared in the preparation step include at least one selected from a group consisting of In—Bi alloys, In—Sn alloys, In—Sn—Ag alloys, Sn—Au alloys, Sn—Bi alloys, Sn—Bi—Ag alloys, Sn—Ag—Cu alloys and Sn—Cu alloys.

18. The method for producing solder particles according to claim 15,
wherein the solder fine particles prepared in the preparation step include at least one selected from a group consisting of In—Bi alloys, In—Sn alloys, In—Sn—Ag alloys, Sn—Au alloys, Sn—Bi alloys, Sn—Bi—Ag alloys, Sn—Ag—Cu alloys and Sn—Cu alloys.

19. The method for producing solder particles according to claim 16,
wherein the solder fine particles prepared in the preparation step include at least one selected from a group consisting of In—Bi alloys, In—Sn alloys, In—Sn—Ag alloys, Sn—Au alloys, Sn—Bi alloys, Sn—Bi—Ag alloys, Sn—Ag—Cu alloys and Sn—Cu alloys.

20. The solder particle according to claim 8, comprising at least one selected from a group consisting of In—Bi alloys, In—Sn alloys, In—Sn—Ag alloys, Sn—Au alloys, Sn—Bi alloys, Sn—Bi—Ag alloys, Sn—Ag—Cu alloys and Sn—Cu alloys.
